(19) United States
(12) Patent Application Publication
(10) Pub. No.: US 2016/0327615 A1
(43) Pub. Date: Nov. 10, 2016

(54) METHOD AND APPARATUS FOR A PORTABLE ELECTRIC VEHICLE SUPPLY EQUIPMENT TESTER

(71) Applicant: Seaward Group, Peterlee (GB)

(72) Inventors: James J. A. Wallace, Sunderland (GB); Simon P. Archbold, Whitley Bay (GB); Andrew D. Osborne, Middlesbrough (GB); Stephen G. B. Rudd, Chester le Street (GB); Anthony Barker, Peterlee (GB)

(21) Appl. No.: 15/143,514

(22) Filed: Apr. 30, 2016

Related U.S. Application Data
(60) Provisional application No. 62/157,077, filed on May 5, 2015.

(51) Int. Cl. G01R 31/40; B60L 11/18

(52) U.S. Cl. CPC G01R 31/40; B60L 11/1809

(57) ABSTRACT

A compact electric vehicle supply equipment tester that performs a comprehensive range of electrical safety and functional tests to measure the performance characteristics of an electric vehicle supply equipment charging station (EVSE). The hand-held, light weight, easy to use tester provides circuitry that simulates the presence of an electric vehicle and provides unique diagnostic capability to identify and determine the cause of EVSE system failures using application software for the electric vehicle supply equipment tester that provides for collected data to be transmitted using a wireless communications interface to provide real-time, remote access and control of the tester to monitor and review test data and fault conditions to assist in fault diagnosis, maintenance, and repair of an EVSE.

### RELATED PATENT APPLICATION

This application claims the benefit of U.S. Provisional Patent Application No. 62/157,077 filed May 5, 2015 entitled METHOD AND APPARATUS FOR A PORTABLE ELECTRIC VEHICLE SUPPLY EQUIPMENT TESTER and which is hereby incorporated herein by reference in the entirety.

### FIELD OF THE INVENTION

The present invention is related to a compact electric vehicle supply equipment tester that performs a comprehensive range of electrical safety and functional tests to measure the performance characteristics of an electric vehicle supply equipment charging station (EVSE). The hand-held, lightweight, easy to use tester provides circuitry that simulates the presence of an electric vehicle EV. The tester further provides unique diagnostic capability to identify and determine the cause of EVSE system failures using application software for the electric vehicle supply equipment tester that provides for collected data to be transmitted using a wireless communications interface to provide real-time, remote access and control of the tester to monitor and review test data and fault conditions to assist in fault diagnosis, maintenance, and repair of an EVSE.

### BACKGROUND

With the growth in popularity of electric and hybrid vehicles there is an increasing number of charging stations to charge the traction battery power supply of an electric vehicle. These charging stations are connected to electrical installations that must be inspected and tested in accordance with the National Electric Code (NFPA 70) to protect people and property from electrical hazards. In addition to the need to ensure that charging points are installed safely and in accordance with regulatory requirements, there is a need to ensure correct operation both at the time of the installation and as part of any on-going service and maintenance regime. However, to understand some of the difficulties associated with ensuring the correct performance of an EVSE charge point, it is important to understand that an EVSE operates and has protection associated with the system to prevent a risk of electric shock. For example, to avoid accidental contact with live electrical parts, the terminals on the EVSE charging cable are not accessible and the EVSE charging output cannot be energized to supply power to an EV unless the charging cable is plugged into the EV and communication between the EVSE system and EV is established. The communication between the EVSE and EV is established using a PWM pilot signal that must have proper voltage, frequency and duty cycle for acceptable communication and operation of the EVSE. A fault within the PWM waveform is difficult to detect and diagnose without the use of more advanced testing equipment such as an oscilloscope, requiring a skilled technician to operate the test equipment and understand the waveform parameters and acceptable tolerance levels. Other commonly applied electrical installation tests, such as ground resistance and CCID trip current testing and some functional testing are not possible unless the EVSE circuit under test is energized and able to supply power to determine if performance characteristics of the EVSE are within acceptable tolerance specifications. Currently, there is not available test equipment that can easily and safely diagnose, measure and monitor the performance and safety functions of an EVSE when a vehicle is not connected.

Common practice for evaluating the performance of an EVSE is to construct a simple test box containing diode/resistor EV simulation circuits to energize the EVSE, such as the electric vehicle test equipment of the prior art to Dickinson et al. U.S. Pat. No. 8,447,543 which discloses a test unit that simulates a pilot line signal using circuitry to initiate a pilot voltage drop to confirm the readiness of the test unit to accept energy from the EVSE. The test unit simulates an electric vehicle using a plurality of resistor banks and control switches to approximate the load of an electric vehicle under different electrical conditions. The test unit includes a forced air cooling system that with the resistor banks simulating a 6.6 kW electrical load results in the test unit being physically large and heavy. The test unit control panel provides minimal diagnostic information where the test unit provides discreet mechanical switches to manually invoke each test and only a series of indicator lights such as LEDs or a small text display appear to provide the operator with limited data in relation to the operation of the EVSE under test. For example indicator 1050 in FIG. 10 lists pilot signal conditioning for amplitude measurement, for frequency measurement and for duty cycle measurement but the disclosure fails to provide or make clear if (or how) this measured data is available to the user.

A further disclosure in U.S. Pat. No. 8,633,678 to Yegin et al., describes an overcurrent protection circuit for an EVSE that is integrated with a controller of the electric vehicle supply circuit to prevent excessive current from flowing to an electric vehicle. The overcurrent protection circuit includes a charge circuit interrupting device (CCID) to interrupt the flow of power from a power source to the electric vehicle if a current sensor coupled to the controller of the EVSE detects a current that exceeds a limit for a first predetermined period of time. The EVSE may then automatically reset after a prescribed period of time, may be manually reset, may have an alarm sound, or may require or perform other actions to have the EVSE operate in response to the detected current limit. The disclosure to Yegin while describing the operational circuitry of the EVSE including the PWM pilot signal, however fails to disclose a portable tester or circuitry that simulates a battery power supply of an electric vehicle that provides diagnosis of the performance characteristics of an EVSE.

A portable testing device, that is still quite large and appears somewhat awkward to use is disclosed in U.S. Pat. No. 9,164,138 to Bianco. The Bianco tester has an input connector positioned on one side of the device with control switches, indicator lights or a small display positioned on the other side of the device. A handle extends from the base of the unit requiring that the unit be held while taking readings. The device appears to provide limited information on the available current, the AC supply voltage, and the pilot signal with LEDs or other indicators providing only pass or fail status of any EVSE performance characteristic. Again, the Bianco tester provides only switches that must be operated manually to energize the EVSE and test, for example, the GFCI. The source of a failure or other diagnosis of failure would require additional more advanced test equipment such as an oscilloscope and a skilled technician to operate the equipment and understand the waveforms or other data that may indicate the reason for a failure. The device further appears to not provide any output of test results through a wireless communications interface.

What is needed is a more compact, easier to use EVSE testing system that provides for the transmission, review and storage of data collected for fault diagnosis or routine inspection to ensure safe operation during the service life of EVSE equipment as disclosed in the present invention.

### SUMMARY OF THE INVENTION

The present invention is a compact, hand held, battery powered EVSE tester that simulates the presence of an electric vehicle and performs a comprehensive range of electrical safety and functional tests on an electric vehicle supply equipment charging station (EVSE). The instrument provides real time measurement and display of key operational values and parameters including supply voltage, ground resistance, and maximum available charging current. The EV100 tester also performs tests to verify the operation and diagnose failures of the ground fault current interrupter (GFCI), charging circuit interrupter device (CCID) circuitry, the proximity latching circuitry, a venting system, and the insulation of cables and wiring. The initiation and validation of the control pilot signal and circuitry is also tested whilst additional measurement data such as the pulse width modulation (PWM) amplitude, the frequency, duty cycle, and state transition times are recorded and can be viewed through the EV100 tester software application on a digital device such as a computer system, laptop, or an iPhone, iPad, tablet, smart phone or other mobile device providing for more in-depth diagnosis of failure by the operator and skilled technicians that may be remote to the location of the EVSE as required.

The tester that may be referred to herein as the EV100 Tester comprises a housing, operational controls to activate the safety and functional tests, and a LCD display having graphical indicators to display electrical readings, indicate test being performed, and display state, results and status of the EVSE. The EV100 tester has an input connector test port that may be in the form of a J1772 standard cable connector for the direct attachment of the EVSE electrical supply cable. The EV100 tester also provides test adaptor cables of various connector configurations to adapt the device for connection to EVSE's having different supply cable connectors. The EV100 tester with and without the test adaptor cable may simulate electric vehicles of various current ratings to detect if the EVSE properly adjusts the maximum available current based on the EV requirements, reducing a risk of supplying power at currents that may damage the EV or cause electric shock. The EV100 tester further provides audible and visual indicators, symbols, icons, and colored displays to show the acceptable operational limits and parameters and to indicate measured and calculated values that are outside of these parameters indicating faults and failures in performance. The EV100 tester can further transmit test results and performance values to assist in the diagnosis and repair of failed EVSE systems.

The present invention is related to an electric vehicle supply equipment tester, comprising a housing; a display panel; operational controls; and circuitry comprising a microprocessor and memory disposed in the housing to measure, calculate, record and transmit performance characteristic data of an electric vehicle supply equipment charging station and wherein information on the test being performed, the status of the electric vehicle supply equipment charging station, the transition states of the electric vehicle supply equipment charging station, and the actual reading of a measured or calculated value may be displayed within the display panel. The electric vehicle supply equipment tester may comprise a wireless interface to transmit performance characteristic data from the electric vehicle supply equipment tester for recording and display within an electric vehicle supply equipment tester software application implemented on a digital device, the digital device having a microprocessor, memory, data storage, and an output device for the transformation and display of data recognizable to a user. The electric vehicle supply equipment tester and electric vehicle supply equipment tester software application may comprise status indicators displaying information recognizable to a user indicating performance characteristic data as within or exceeding acceptable tolerance specifications and record and display pass symbols within the display of an output device to indicate that a measured or calculated value is within specified tolerances and to record and display fault symbols within the display of an output device to indicate that a measured or calculated value is outside specified tolerances. The electric vehicle supply equipment tester may display pass symbols within the display panel to indicate that a measured or calculated value is within specified tolerances and fault symbols within the display panel to indicate that a measured or calculated value is outside specified tolerances. The electric vehicle supply equipment tester software application may record and display measured and/or calculated values and pulse width modulation signals of the performance characteristic data and the transition states and timing of changes in transition states of the electric vehicle supply equipment charging station within the display of the output device removing the requirement of an oscilloscope for diagnosis.

The electric vehicle supply equipment tester may comprise proximity drive circuitry to simulate the mechanical connection of an electric vehicle to the electric vehicle supply equipment charging station. The electric vehicle supply equipment tester may comprise a plurality of adaptor test cables to simulate various current ratings of different electric vehicles. The electric vehicle supply equipment tester may comprise proximity simulation control circuitry to simulate various current ratings of different electric vehicles. The electric vehicle supply equipment tester may comprise pulse width modulation positive peak measurement circuitry, pulse width modulation negative peak measurement circuitry, and pulse width modulation frequency/duty cycle measurement circuitry for the measurement of a pulse width modulation signal. The electric vehicle supply equipment tester may comprise phase-ground loop resistance measurement circuitry for the calculation of ground resistance. The electric vehicle supply equipment tester may comprise ground fault current interrupter test signal generation circuitry and a ground fault current interrupter current generator to test the ground fault current, ground fault current interrupter and charging circuit interrupting device of an electric vehicle supply equipment charging station. The electric vehicle supply equipment tester may comprise insulation test voltage circuitry to test the insulation of an electric vehicle supply equipment charging station supply cable.

The present invention is related to a method of testing an electric vehicle supply equipment charging station comprising measuring performance characteristics of an electric vehicle supply equipment charging station; calculating performance characteristics of the electric vehicle supply equipment charging station; recording and displaying measured and calculated performance characteristic data. The method of testing an electric vehicle supply equipment charging station may comprise transmitting all measured and calculated performance characteristic data to an electric vehicle supply equipment tester software application implemented on a digital device, the digital device having a microprocessor, memory, data storage, and an output device for the transformation and display of the measured and calculated performance characteristic data in a form recognizable to a user. The method of testing an electric vehicle supply equipment charging station may comprise recording and displaying status indicators as information recognizable to a user indicating performance characteristic data as within or exceeding acceptable tolerance specifications. The method of testing an electric vehicle supply equipment charging station may comprise recording and displaying information on the test being performed, the status of the electric vehicle supply equipment charging station, the detection status of the electric vehicle supply equipment charging station, and test results indicating the actual reading of a measured or calculated value. The method of testing an electric vehicle supply equipment charging station may comprise selecting an auto operational control; connecting the electric vehicle supply equipment charging station to an electric vehicle supply equipment tester, the electric vehicle supply equipment tester simulating the connection of an electric vehicle; setting on the tester a maximum current to be tested; measuring the maximum charging current supplied by the electric vehicle supply equipment charging station; determining if the maximum charging current is within a specified range of the maximum current set by the tester; recording and displaying a status indicator indicating the maximum charging current of the electric vehicle supply equipment charging station as passing if within the specified range; and recording and displaying a status indicator indicating the maximum charging current of the electric vehicle supply equipment charging station as failing if outside the specified range.

The method of testing an electric vehicle supply equipment charging station may comprise selecting a maximum current to be tested based on the maximum current rating of a cable adaptor; connecting the electric vehicle supply equipment charging station to the cable adaptor; connecting the cable adaptor to an electric vehicle supply equipment tester; measuring the maximum charging current supplied by the electric vehicle supply equipment charging station; determining if the maximum charging current is within a specified range of the maximum current set by the cable adaptor; recording and displaying a status indicator indicating the maximum charging current of the electric vehicle supply equipment charging station as passing if within the specified range; and recording and displaying a status indicator indicating the maximum charging current of the electric vehicle supply equipment charging station as failing if outside the specified range. The method of testing an electric vehicle supply equipment charging station may comprise connecting the electric vehicle supply equipment charging station to a cable adaptor; connecting the cable adaptor to an electric vehicle supply equipment tester; applying a test voltage between the power terminals and ground of the electric vehicle supply equipment charging station; measuring any current flow; calculating and displaying the insulation resistance; determining if any current flow is within a specified tolerance; recording and displaying a status indicator indicating the current flow and insulation resistance as passing if within the specified tolerance; and recording and displaying a status indicator indicating the current flow and insulation resistance as failing if outside the specified tolerance.

The method of testing an electric vehicle supply equipment charging station may comprise detecting, recording and displaying the connection of the electric vehicle supply equipment charging station to an electric vehicle supply equipment tester; recording and displaying a detection status as “State A”; detecting a reduction in the control pilot signal from +/−12 VDC to +/−9 VDC simulating the connection of an electric vehicle using the electric vehicle supply equipment tester; recording and displaying the detection status as “State B”; measuring and recording the pulse width modulation positive peak voltage; measuring and recording the pulse width modulation negative peak voltage; measuring and recording the pulse width modulation frequency; measuring and recording the pulse width modulation duty cycle; detecting a reduction in the control pilot signal from +/−9 VDC to +/−6 VDC; detecting, recording and displaying the closing of the main power contact; supplying power to the electric vehicle supply equipment tester simulating the connection of an electric vehicle; recording and displaying the detection status as “State C”; detecting, recording and displaying the opening of the main power contact; stopping the supply of power to the electric vehicle supply equipment tester simulating the connection of an electric vehicle; recording and displaying the detection status as “State E” detecting the disconnection of the electric vehicle supply equipment charging station to the electric vehicle supply equipment tester; recording and displaying a detection status as “State F”. The method of testing an electric vehicle supply equipment charging station may comprise selecting the vent fan check operational control; simulating an electric vehicle requiring a ventilation system; determining that the electric vehicle supply equipment charging station has a ventilation system and that the ventilation system turns on prior to charging; displaying at least one indicator showing the ventilation system as running and the electric vehicle supply equipment charging station as charging; recording and displaying the detection status as “State D”. The method of testing an electric vehicle supply equipment charging station may comprise determining the electric vehicle supply equipment charging station does not have a ventilation system; determining the electric vehicle supply equipment charging station provides an indicator that the electric vehicle charging station will not charge because it does not have a ventilation system; determining that the electric vehicle charging station does not provide a charge; recording and displaying a status indicator as passing if the electric vehicle charging station does not provide a charge. The method of testing an electric vehicle supply equipment charging station may comprise selecting the ground fault current interrupter operational control; calculating the resistance of the ground conductor connection of the electric vehicle supply equipment charging station; producing a controlled fault current in the ground conductor connection; increasing the controlled fault current to a maximum controlled fault current; determining if the ground fault current interrupter stops the flow of AC power to the electric vehicle supply equipment charging station prior to reaching a predetermined threshold for the controlled fault current; recording and displaying at least one status indicator as passing if the ground fault current interrupter stops the flow of AC power to the electric vehicle supply equipment charging station prior to reaching the predetermined threshold for the controlled fault current; and recording and displaying at least one status indicator as failing if the ground fault current interrupter does not stop AC power to the electric vehicle supply equipment charging station prior to the controlled fault current reaching the predetermined threshold for the controlled fault current.

The present invention is related to a computer readable medium of instructions for testing an electric vehicle supply equipment charging station, comprising instructions for measuring performance characteristics of an electric vehicle supply equipment charging station; instructions for calculating performance characteristics of the electric vehicle supply equipment charging station; and instructions for recording and displaying measured and calculated performance characteristic data. The computer readable medium of instructions for testing an electric vehicle supply equipment charging station may comprise instructions for transmitting, recording and displaying all measured and calculated performance characteristic data within a software application implemented on a digital device, the digital device having a microprocessor, memory, data storage, and an output device for the transformation and display of data recognizable to a user. The computer readable medium of instructions for testing an electric vehicle supply equipment charging station may comprise instructions for recording and displaying status indicators as information recognizable to a user indicating performance characteristic data as within or exceeding acceptable tolerance specifications. The computer readable medium of instructions for testing an electric vehicle supply equipment charging station may comprise instructions for recording and displaying information on the test being performed, the status of the electric vehicle supply equipment charging station, the detection status of the electric vehicle supply equipment charging station, the time for transition between states of the detection status, and test results indicating the actual reading of measured and calculated values. The computer readable medium of instructions for testing an electric vehicle supply equipment charging station may comprise instructions for determining the selection of the auto operational control; instructions determining the connection of the electric vehicle supply equipment charging station to an electric vehicle supply equipment tester, the electric vehicle supply equipment tester simulating the connection of an electric vehicle; instructions for setting a maximum current to be tested; instructions for measuring the charging voltage of the electric vehicle supply equipment charging station; instructions for measuring the maximum charging current supplied by the electric vehicle supply equipment charging station; instructions for determining if the maximum charging current is within a specified range of the set maximum current; instructions for recording and displaying a status indicator indicating the maximum charging current of the electric vehicle supply equipment charging station as passing if within the specified range; and instructions for recording and displaying a status indicator indicating the maximum charging current of the electric vehicle supply equipment charging station as failing if outside the specified range. The computer readable medium of instructions for testing an electric vehicle supply equipment charging station may comprise instructions for determining a maximum current rating of a cable adaptor; instructions for determining the connection of the electric vehicle supply equipment charging station to the cable adaptor; instructions for determining the connection of the cable adaptor to an electric vehicle supply equipment tester; instructions for measuring the charging voltage of the electric vehicle supply equipment charging station; instructions for measuring the maximum charging current supplied by the electric vehicle supply equipment charging station; instructions for determining that the maximum charging current is within a specified range of the maximum current set by the cable adaptor; instructions for displaying a status indicator indicating the maximum charging current of the electric vehicle charging station as passing if within the specified range; and instructions for displaying a status indicator indicating the maximum charging current of the electric vehicle charging station as failing if outside the specified range. The computer readable medium of instructions for testing an electric vehicle supply equipment charging station may comprise instructions for determining the connection of the electric vehicle supply equipment charging station to the cable adaptor; instructions for determining the connection of the cable adaptor to an electric vehicle supply equipment tester; instructions for applying a test voltage between the power terminals and ground of the electric vehicle supply equipment charging station; instructions for measuring any current flow; instructions for calculating and displaying the insulation resistance; instructions for determining if any current flow is within a specified tolerance; instructions for displaying a status indicator indicating the current flow and insulation resistance as passing if within the specified tolerance; and instructions for displaying a status indicator indicating the current flow and insulation resistance as failing if outside the specified tolerance. The computer readable medium of instructions for testing an electric vehicle supply equipment charging station may comprise instructions for detecting the connection of the electric vehicle supply equipment charging station to the electric vehicle supply equipment tester; instructions for displaying a detection status as “State A”; instructions for detecting a reduction in the control pilot signal from +/−12 VDC to +/−9 VDC to simulate the connection of an electric vehicle using the electric vehicle supply equipment tester; instructions for displaying the detection status as “State B”; instructions for measuring, recording and displaying the pulse width modulation signal comprising a positive peak voltage, a negative peak voltage, a modulation frequency, and duty cycle; instructions for detecting a reduction in the control pilot signal from +/−9 VDC to +/−6 VDC; instructions for detecting the closing of the main power contact; instructions for supplying power to the electric vehicle supply equipment tester simulating the connection of an electric vehicle; instructions for displaying the detection status as “State C”; instructions for detecting the opening of the main power contact; instructions for stopping the supply of power to the electric vehicle supply equipment tester simulating the connection of an electric vehicle; instructions for displaying the detection status as “State E”, instructions for detecting the disconnection of the electric vehicle supply equipment charging station to the electric vehicle supply equipment tester; instructions for displaying the detection status as “State F”. The computer readable medium of instructions for testing an electric vehicle supply equipment charging station may comprise instructions for determining the selection of the vent fan check operational control; instructions for simulating an electric vehicle requiring a ventilation system; instructions for determining that the electric vehicle supply equipment charging station has a ventilation system and turns the ventilation system on prior to charging; instructions for displaying at least one indicator showing that the ventilation system as running and the electric vehicle supply equipment charging station as charging instructions for displaying the detection status as “State D”. The computer readable medium of instructions for testing an electric vehicle supply equipment charging station may comprise instructions for determining that the electric vehicle supply equipment charging station does not have a ventilation system; instructions for determining that the electric vehicle supply equipment charging station provides an indicator that the electric vehicle supply equipment charging station will not charge because it does not have a ventilation system; instructions for determining that the electric vehicle supply equipment charging station does not provide a charge; instructions for displaying a status indicator as passing if the electric vehicle supply equipment charging station does not provide a charge. The computer readable medium of instructions for testing an electric vehicle supply equipment charging station may comprise instructions for determining the selection of the ground fault current interrupter operational control; instructions for calculating the resistance of the ground conductor connection of the electric vehicle supply equipment charging station; instructions for producing a controlled fault current in the ground conductor connection; instructions for increasing the controlled fault current to a maximum controlled fault current; instructions for determining if the ground fault current interrupter stops the flow of AC power to the electric vehicle supply equipment charging station prior to reaching a predetermined threshold for the controlled fault current; instructions for recording and displaying at least one status indicator as passing if the ground fault current interrupter stops the flow of AC power to the electric vehicle supply equipment charging station prior to reaching the predetermined threshold for the controlled fault current; and instructions for recording and displaying at least one status indicator as failing if the ground fault current interrupter does not stop AC power to the electric vehicle supply equipment charging station prior to the controlled fault current reaching the predetermined threshold for the controlled fault current.

These and other features, advantages and improvements according to this invention will be better understood by reference to the following detailed description and accompanying drawings.

### BRIEF DESCRIPTION OF THE DRAWINGS

Several embodiments of the present invention will now be described by way of example only, with reference to the accompanying drawings in which:

FIG. 1 is a is a diagrammatic representation of a server computer system in an embodiment of the EV100 tester software application of the present invention;

FIG. 2 is a is a diagrammatic representation of a communications network in an embodiment of the EV100 tester software application and EV100 tester of the present invention;

FIG. 3 is an embodiment of the EV100 tester of the present invention;

FIG. 4 is an embodiment of an adaptor cable with an embodiment of the EV100 tester and an electric vehicle supply equipment (EVSE) system;

FIG. 5 is an embodiment of an adaptor cable connector in an embodiment of the EV100 tester of the present invention;

FIG. 6 is an embodiment of a function block diagram in an embodiment of the EV100 tester of the present invention;

FIG. 7 is an embodiment of the display panel of the EV100 tester of the present invention showing the EV detection status in “State A” as ready;

FIG. 8 is an embodiment of a control pilot signal PWM diagram in an embodiment of the EV100 tester of the present invention;

FIG. 9 is an embodiment of the display panel of the EV100 tester of the present invention showing the EV detection status in “State B” as ready;

FIG. 10 is an embodiment of the display panel of the EV100 tester of the present invention showing the EV detection status in “State B” showing a test fault status;

FIG. 11 is an embodiment of the display panel of the EV100 tester of the present invention showing the EV detection status in “State B” showing a test pass status;

FIG. 12 is an embodiment of the display panel of the EV100 tester of the present invention showing the EV detection status in “State C” as charging;

FIG. 13 is an embodiment of the display panel of the EV100 tester of the present invention showing the EV detection status in “State D” showing a ventilation system test status as running;

FIG. 14 is an embodiment of the display panel of the EV100 tester of the present invention showing the EV detection status in “State B” showing a ventilation system test status as stopped;

FIG. 15 is an embodiment of the display panel of the EV100 tester of the present invention showing the EV detection status in “State B” showing a test fault status;

FIG. 16 is an embodiment of the display panel of the EV100 tester of the present invention performing a GFCI test;

FIG. 17 is an embodiment of the display panel of the EV100 tester of the present invention showing a GFCI test as passing;

FIG. 18 is an embodiment of the display panel of the EV100 tester of the present invention showing a cable insulation test as passing;

FIG. 19 is an embodiment of the EV100 tester of the present invention transmitting data to the EV100 tester software application;

FIG. 20 is an embodiment of the EV100 tester software application transmitting test result data from the EV100 tester to a database;

FIG. 21 is an embodiment of the EV100 tester software application transmitting test result data from a database to a communications network;

FIG. 22 is an embodiment of the EV100 tester software application transmitting test result data from the EV100 tester from a database to another digital device;

FIG. 23 is a further embodiment of the EV100 tester software application; and

FIG. 24 is an embodiment of the EV100 tester and a NFC communications network for the transmission of data using the EV100 tester software application.

### DETAILED DESCRIPTION OF THE INVENTION

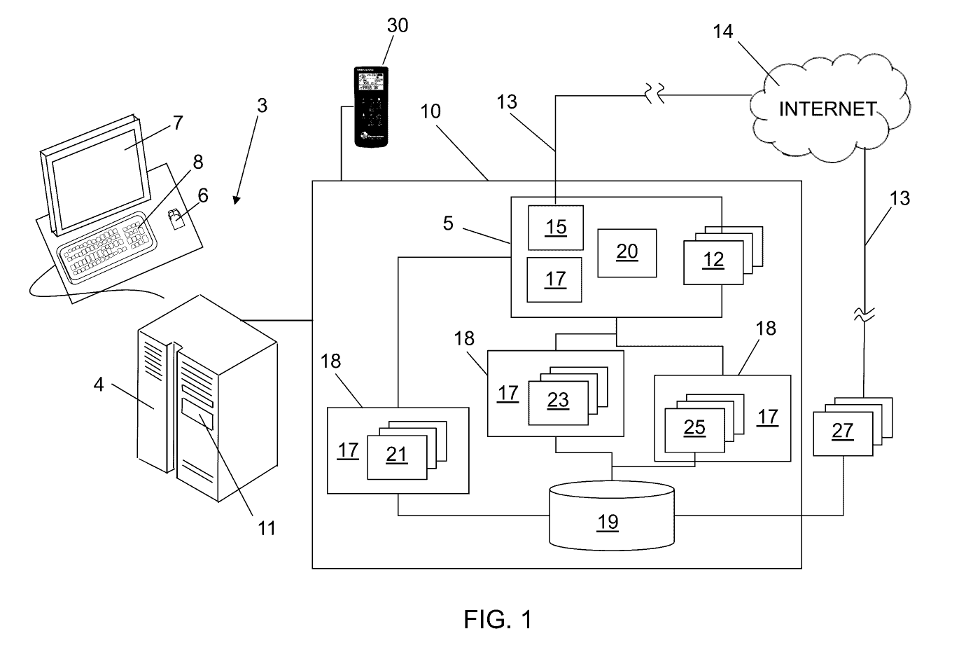

The EV100 tester 30 collects data on the performance and characteristics of an EVSE and presents this data to the electrician 29, technician or other operator through an easy to recognize and understand graphical visual display 40 to provide the status of the EVSE. The test data may include results for the testing of line voltage, grounding, testing of the venting system, operation of the ground fault current interrupter (GFCI), charging circuit interrupting device testing (CCID), pilot signal testing, proximity circuit testing, and maximum current rating of the EVSE supply and EVSE supply cable. Data from the EV100 tester 30 is provided through a near field communication interface and/or a wireless communications interface to the EV100 tester software application that is available on a mobile device or other digital device that provides for remote monitoring, review of data, and diagnosis to determine faults within the EVSE system under test. As shown in FIG. 1, there is illustrated a computer system 3 as a digital device for implementing the EV100 tester software application to present data from the EV100 tester 30 of the present invention. Although a computer system 3 is shown for the purpose of illustrating an embodiment, the presentation of data from the EV100 tester 30 within a software application is not limited to the computer system 3 shown, but may be used with any electronic processing system such as found in digital communications devices, cellular phones and other mobile devices, home computers, laptop computers, tablet computers, or any other system for the processing of digital data. The computer system 3 includes a server computer 4 having a microprocessor-based unit 5 (also referred to herein as a processor) for receiving and processing software programs, transforming data and for performing other processing functions. An output device 7 such as a visual display is electrically connected to the microprocessor-based unit 5 for displaying user-related information associated with the software application, e.g., by means of a graphical user interface. An input device such as a keyboard 8 may also be connected or integrated within the digital device. The input device is connected to the microprocessor-based unit 5 for permitting a user to input information to the software application program. As an alternative or in addition to using the keyboard 8 for input, a mouse 6 may be used for moving a selector on the display or alternatively a touch screen or other input device may be provided for accessing data, selecting items and performing operations within the software application.

The output device 7 provides visually to the user transactional data that has been subject to transformations from the measured data and calculated results from the EV100 tester 30 and from the EV100 tester software application of the present invention implemented on a digital device. The output device 7 can be a monitor, a tablet computer, or other visual computer screen or graphical user interface (GUI) a printer or other digital device that provides a visual or other type representation of a final output from the microprocessor-based unit 5. The output device 7 can also be an output device that provides the transactional data as a digital file. The microprocessor-based unit 5 provides means for processing the transactional data to produce readily discernible, informational and organized images and data on the intended output device 7 or media. The present invention can be used with a variety of other output devices that can include, but are not limited to, a digital camera, a photographic printer and soft copy display. Those skilled in the art will recognize that the present invention is not limited to just these mentioned data processing functions. The server computer 4 shown in FIG. 1 can store computer programs by having a program stored in an internal or external computer readable storage medium 11, which may include, for example: magnetic storage media such as a magnetic disk or magnetic tape; optical storage media such as an optical disc, optical tape, or machine readable bar code; solid state electronic storage devices such as random access memory (RAM), read only memory (ROM) or USB mass storage devices, flash memory or other data storage devices. The associated computer programs may be stored locally and or remotely on a virtual machine (VM) or data center using any other physical device or medium employed to store a computer program indicated by offline memory device. For example, the method can be performed using a system including one or more digital communications interfaces and devices and/or one or more personal computer systems. The digital devices may be connected wirelessly, using WiFi, Bluetooth, cellular or other radio-frequency links, and it is to be appreciated that such devices can be mobile devices (e.g., iPod, iPad, tablet computer, notebook, laptop, smart phone, or cell phone that can be used as a processing unit, a display unit, and/or a unit to give processing instructions), and as a service offered through a network connection 13 via the interne 14.

Embodiments of the EV100 tester software application 10 may be built using a combinations of HTML, CSS, Java Script, JQuery, and PHP or other software languages where those skilled in the art will readily recognize that the equivalent of such software may also be constructed in computer, electrical and communications hardware. The EV100 tester software application 10 may have a communications interface 15, code related to the software application 17 and administrative tools 20. The communications interface 15 may be an email server to transmit messages and notifications to users of the EV100 tester software application 10. The administrative tools 20 set and prioritize access and features to users based on requirements of use. Data records 12 such as EVSE specifications, EVSE model numbers, and regulatory requirements may be accessible to some or all users as determined by the review and monitoring requirements of the test data and administrative access established for each user. Because data manipulation algorithms and systems are well known, the present description emphasizes algorithms and features forming part of, or cooperating more directly with the method and hardware of the presently disclosed invention. General features of databases, digital communications devices, email and computerized systems are likewise well known, and the present description is generally limited to those aspects directly related to the method and related hardware of the invention. Other aspects of such algorithms and apparatus, and hardware and/or software for producing and otherwise processing the data involved therewith, not specifically shown or described herein may be selected from such systems, algorithms, components, and elements known in the art.

Implementation of the EV100 tester software application 10 may be in conjunction with one or more database management systems (DBMS) 19 such as Oracle, IBM DB2, Microsoft SQL Server, PostageSQL, MySQL, or others using widely supported database languages such as SQL to define and manipulate data and perform data queries. Other aspects of such algorithms and apparatus, and hardware and/or software for producing and otherwise processing the data involved therewith, not specifically shown or described herein may be selected from any such systems, algorithms, components, and elements known in the art. The software application and computer platform may be hosted on a SSL, SSL 256, SHTTP bit secured server as a fully redundant data center. The platform may have multiple levels of security and layers of redundancy built in to make sure that all data and personal information is secured and not open to the public. Data replication and redundancy may be performed automatically and all servers may be secured in optimal conditions. The implementation may further provide synchronization of local and remote desktop clients using virtual machine check in and check out operations to maintain access to the most recently updated local or remote copies that reflect user changes to software programs and accessed data files.

In each context, the invention may stand alone or may be a component of a larger system solution. Furthermore, human interfaces, e.g., the input, the digital processing, the display to a user, the input of user requests or processing instructions, the output, can each be on the same or different devices and physical locations, and communication between the devices and locations can be via public or private network connections, or media based communication. Where consistent with the foregoing disclosure of the present invention, aspects of the method of the invention can be fully automatic, may have user input (be fully or partially manual), may have user or operator review to accept/reject the result, or may be assisted by data or metadata (data or metadata that may be user supplied, supplied by another computer program or database from a different application or determined by an algorithm). Moreover, the algorithm(s) may interface with a variety of workflow user interface schemes.

The EV100 tester software application 10 of the present invention may be implemented through the application software 17 downloaded to the server 4 and/or as a web-native software application delivery model or SaaS (Software as a Service) to be hosted and operated as an on demand computing service such as a cloud or shared resource database through a web browser using the internet 14 through an internet connection 13. The EV100 tester software application 10 may include policies and protocols in cloud description language (CDL) and domain specific languages (DSL) for this implementation to manage and monitor secure access and system usage to one or more domains to provide multiple virtual servers 18 with each server serving one or more instantiations of the EV100 tester software application 10. Security of the virtual server 18 is provided by having a separate virtual server 18 setup for each charging station site 24 using a unique domain name that may be active solely during a maintenance, testing or diagnostic period, and may if desired be immediately deactivated upon completion of an activity or at any time. Each virtual server 18 has data storage where unique data records 21, 23, and 25 specific to the charging station 24 are secured. External data 27 including regulatory standards may be available through a network and/or internet connection 13. At all times, the charging station's transactional data and test data content is protected from unauthorized access and copying through secure management protocols of the EV100 tester software application 10. At completion of required maintenance or another test protocol, access to the EV100 tester software application 10 may be inactivated and the entire database with all data may be ported to a storage unit and be provided to the charging station 24 as a secure record of all processing steps, communications and transactional data of the test procedure, data and results.

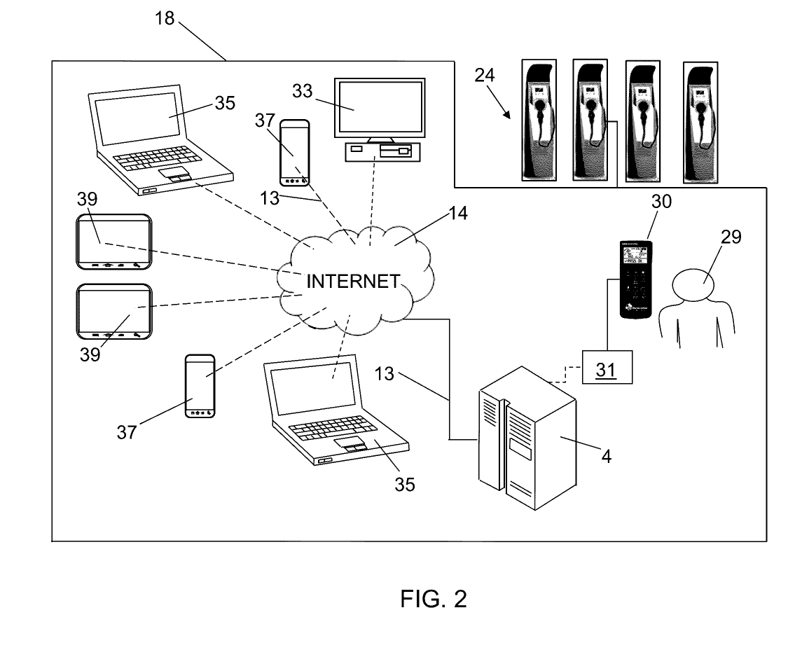

Users of the EV100 tester software application 10 associated with a charging station 24 may access the secure virtual server 18 using a unique domain name and then enter a secure login name and password which provides access at different administrative levels based on their use. As shown in FIG. 2, the users may be electricians or other operators 29 that acquire the test data 31 using the EV100 tester 30 and/or other skilled technicians that access the virtual server 18 through their desktop 33, laptop 35, smartphone 37 or tablet 39 computer systems or other digital devices to review and diagnose failures found during testing. Each user may be granted appropriate access to the secure specific domain of the virtual server 18 through an administrator using administrative tools 20 to control the levels of access so as to prevent or limit access to the EV100 tester software application 10 through pre-defined privileges based on responsibility and usage.

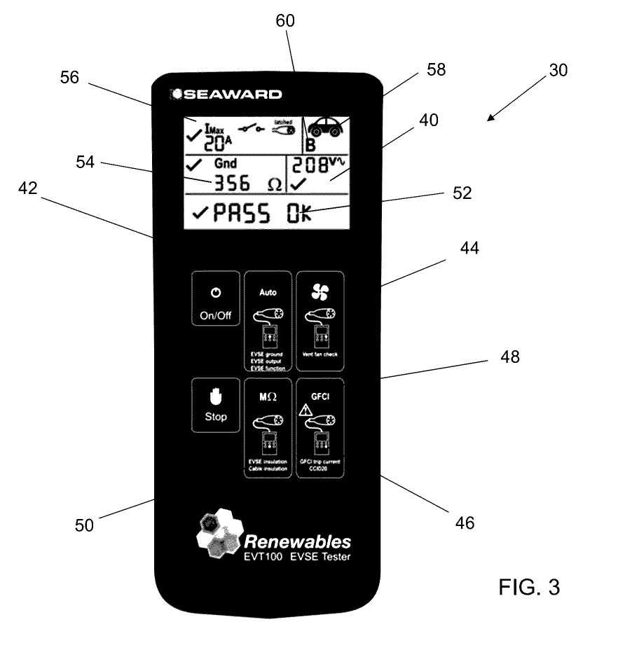

As shown in FIG. 3, the EV100 tester 30 is compact and lightweight with similar weight and dimensions to a multimeter or other small electrical test equipment to easily be held in the hand of the operator 29. The housing 42 may be of a durable, reinforced plastic to protect the internal components of the device. Operational controls 44 are provided for the operator 29 such as an electrician or other technician to select the appropriate test or adjust the information visible within the display 40. Each operational control 44 has an informational icon 46, functional control 48, and labeling 50 to make operation and selection of the functions of the tester 30 easy to use and understand. Status indicators 52, measured values 54, labeling 56, graphics 58, and performance state 60 within the LCD display 40 provide the operator with comprehensive information.

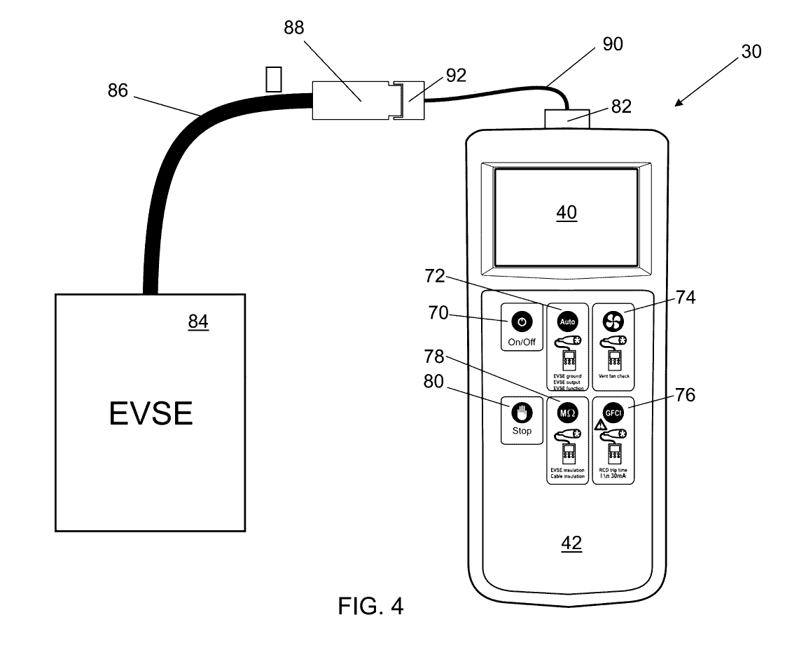

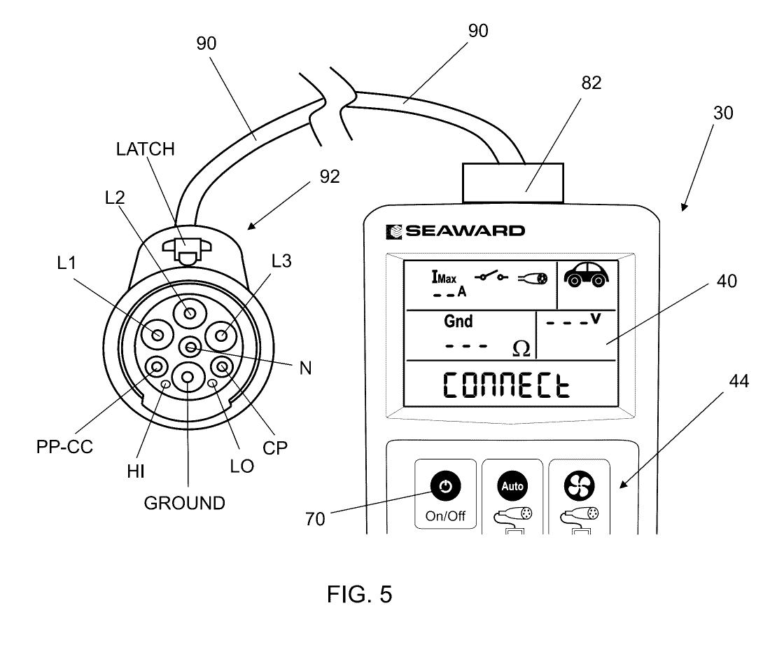

As shown in FIG. 4, the operational controls 44 on the tester 30 may include a power on/off button 70, an auto test operational control 72, a venting system fan check test operational control 74, a ground fault current interrupter (GFCI) test operational control 76, a cable insulation test operational control 78 and a test stop button 80. These operational controls 44 may be electronic switches, mechanical switches, touch screen controls or other types of input controls to functionally operate the EV100 tester 30. An input connector test port 82 may be positioned on the top of the EV100 tester 30 or in other embodiments on the front, back, bottom, or side of the tester 30. The test port 82 provides for the electrical connection of the EV100 tester circuitry to the EVSE system 84 through a tethered EVSE supply cable 86 permanently attached to the EVSE 84, and/or using a test or adaptor cable 90 that may be removable from the EV100 tester 30. A tethered EVSE supply cable 86 has a connector 88 that may be inserted directly into the test port 82 or be inserted into a connector 92 of an adaptor cable 90 that is then connected to the EV100 tester 30. A range of adaptor cables 90 with various types of cable connectors 92 may be available for various commonly used EVSE charging connector types providing for the EVSE tester 30 to be universally compatible with different types of EVSE systems 84. In embodiments of the multi-way test port 82 and in some embodiments of the adaptor cable connector 92, test terminals for up to three phases (L1, L2 and L3), Neutral (N), Ground (GND) Control Pilot (CP), and Proximity (PP-CC) are provided to accommodate various EVSE power supply configurations, as shown in FIG. 5. A Link Hi/Lo switch may be provided for the automatic detection of the test adaptor cable 90.

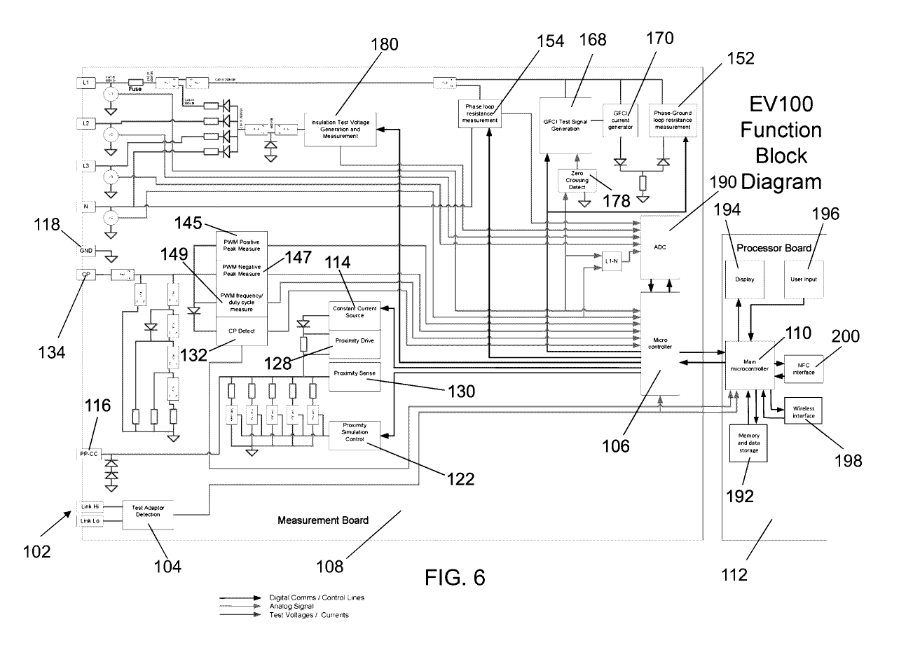

In embodiments of the present invention, when the on/off power button 70 is selected, the EV100 tester 30 is in an initialization state, waiting for the connection of the EVSE supply cable 86. The EVSE supply cable 86 may be connected directly or by using the adaptor cable 90. If the adaptor cable 90 is used, the adaptor cable 90 is detected using the Link Hi/Lo detector switch 102 and test adaptor detection circuitry 104 that sends a signal to the onboard microcontroller 106 of the measurement board 108 and the main microcontroller 110 of the processor board 112 as shown in the EV100 Function Block Diagram in FIG. 6. The test adaptor cable 90 is fitted with a coding resistor to test the adjustment of the maximum available charging current of the EVSE based on the maximum current rating of the electric vehicle. The constant current source 114, measures the coding resistance in the EVSE supply charging cable 86 between the PP-CC connector 116 and ground 118. The EV100 tester 30 will verify that the cable coding resistance is within the range specified by SAE J1772 and display the maximum current rating of the tethered cable adaptor 90.

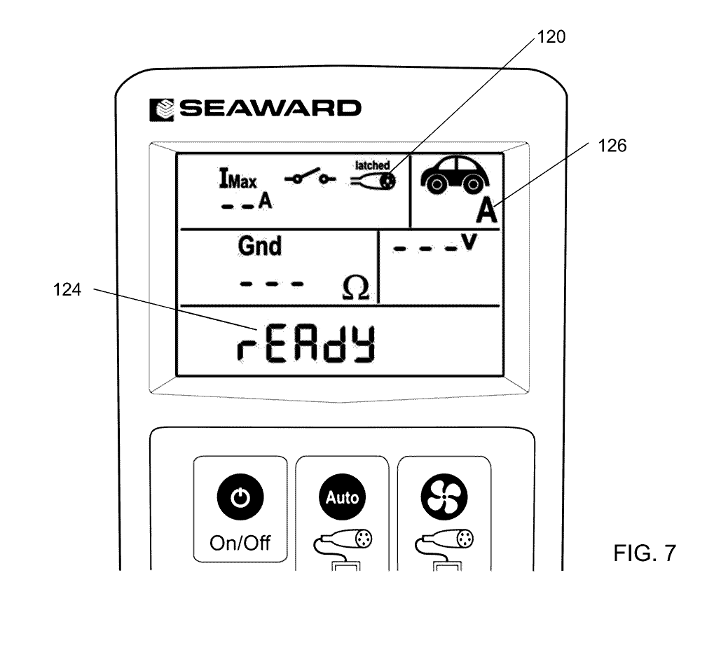

If the EVSE supply cable 86 is connected directly to the EV100 multi-way test port 82, the cable coding resistor proximity simulation control circuitry 122 shown in the EV100 Function Block Diagram, simulates the presence of a vehicle supply charging cable. Embodiments of the 100 EV100 tester 30 can simulate a range of charging cables from 16 A to 70 A which provides for testing of the operation of the EVSE maximum current detection circuitry. By simulating the presence of a vehicle supply charging cable having a lower current rating than the maximum current rating of the EVSE 84, the EVSE 84 must correctly detect the lower current rating and reduce the maximum available charging current accordingly. For example, when testing an EVSE 84 that can deliver a maximum current of 32 A and the EV100 tester 30 simulates the presence of a charging cable having a maximum current rating of 16 A, the EVSE 84 should signal that the maximum available charging current is 16 A, not 32 A. In a further example, if the simulated maximum current rating of the cable is 70 A, the EVSE 84 should still supply a maximum available charging current of 32 A and signal that 32 A is the maximum current being delivered, not 70 A. The proper operational signals from the EVSE 84 and the maximum available charging current results for simulations for cables at different maximum current ratings is stored and transmitted to the EV100 tester software application 10. These initialization steps for the connection of the EVSE supply cable 86 and simulating and determining the proper adjustment of the EVSE maximum current rating based on the current rating of the connected cable are performed by the EV100 tester 30 if any one of the Auto 72, Vent 74, or GFCI 76 operational controls 48 is pressed. The connection of the EVSE 84 to the EV100 tester 30 is shown in the display 40 as “latched” in the connector status 120, as shown in an embodiment of the EV100 tester in FIG. 7.

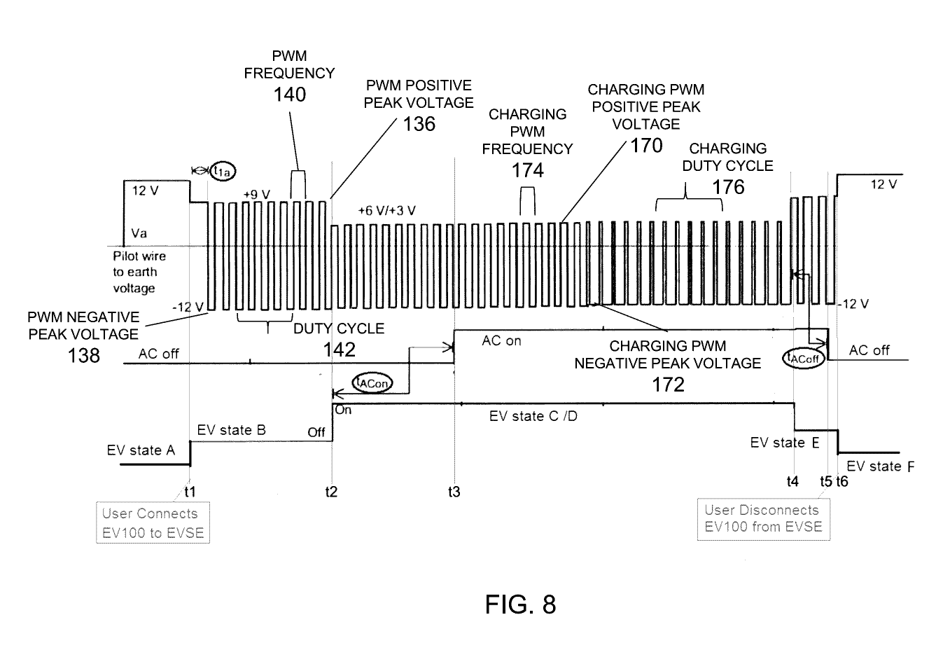

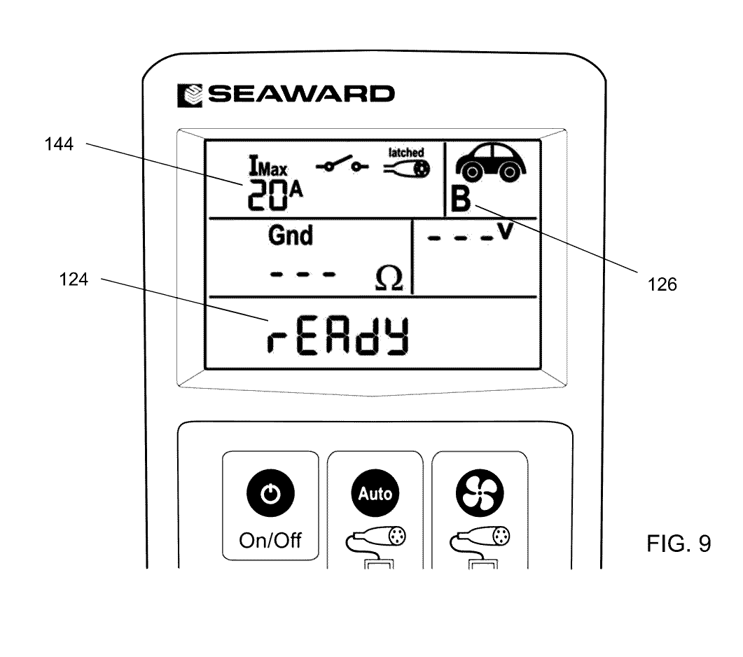

After the initialization steps, an operational status indicator 124 shows the EV100 tester 30 as “READY” and an electric vehicle (EV) simulation indicator 126 shows the EV detection status or transition state as in “State A” as shown in FIG. 7. The EV100 tester 30 will, using the proximity drive circuit 128 and proximity sense circuit 130 of the measurement board 108, adjust the resistance from the proximity input (PP-CC) 116 to ground 118 to transmit a signal to the EVSE 84 that simulates that an electric vehicle is mechanically connected. Using the CP detect circuitry 132, the initial voltage of the control pilot signal CP from the CP input 134 is measured. The detection of the control pilot signal CP enables basic two way communication between the between the EVSE 84 and the EV100 tester 30 with the EV100 tester 30 simulating an EV. With the connection of the EVSE supply cable 86 to the EV100 tester 30 directly or through the cable adaptor 90, the control pilot signal CP voltage is reduced from +/−12 VDC to +/−9 VDC with respect to ground 118. This voltage reduction transitions the EV detection status 126 or transition state to “State B” where communication via a PWM signal on the CP line 134 is initiated and the PWM positive peak voltage 136, the negative peak voltage 138, the PWM frequency 140, and the PWM duty cycle 142 will be interrogated and recorded on the EV100 tester 30, as shown in FIG. 8, and may be sent to the EV100 tester software application 10 for recording and display. The CP line 134 measurements are made using the PWM positive peak measure circuitry 145, PWM negative peak measure circuitry 147, and the PWM frequency/duty cycle measurement circuitry 149 of the measurement board 108 as shown in FIG. 6. Using this information the EV100 tester 30 will determine and display the maximum available charging current 144 reported as shown in FIG. 9.

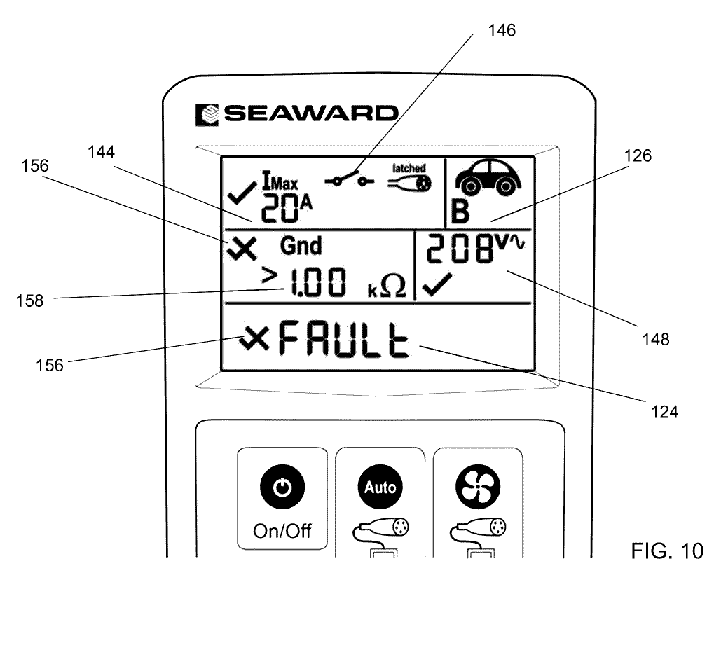

The EV100 tester 30 will then simulate a request from the EV for charging to begin by increasing the resistance to ground 118 at the CP line 134 which will reduce the CP voltage to 6VDC. The EV100 tester 30 will measure the main supply voltage providing electric power to the EVSE 84 from one of the following; between L1 and N, L2 and L3, and between L3 and N in the case of a three phase voltage supply. The voltage measurement 148 is displayed as shown in FIG. 10, and is recorded and transmitted to the EV100 tester software application 10. If the main supply voltage is accurate within a specified tolerance as set through the defaults of the EV100 tester 30 or through the EV100 tester software application 10, the EV100 tester 30 will measure the phase to ground loop impedance and calculate the resistance of the ground connection using the phase-ground loop resistance measurement circuitry 152 of the measurement board 108. The ground resistance is measured using a proprietary non-trip method that allows accurate measurements to be made on circuits protected by a ground fault current interrupter (GFCI) without tripping the EVSE 84. This test verifies that the EVSE 84 is properly grounded. For three phase voltage supplies the phase loop resistance is measured using the phase loop resistance measurement circuitry 154 of the measurement board 108. The phase loop resistance measurement is displayed within the EV100 tester display 40 and may be transmitted to the EV100 tester software application 10. If the supply voltage and ground resistance is outside of the limits of a specified tolerance for the supply voltage or ground resistance as set through the defaults of the EV100 tester 30 or through the EV100 tester software application 10, the operational status indicator 124 will display “FAULT” to indicate that the EVSE 84 is not functioning properly to initiate the charging of an EV, as shown in FIG. 10. A fault symbol 156 will be displayed with the operational status indicator 124 and will be displayed within the display panel 40 to indicate the fault reading of the ground resistance measurement 158 shown as 1.00 k ohms in this example which may be due to a poor ground connection requiring a service technician to investigate the source of the fault. A series of further tests as described herein may be performed to assist in the determination of the fault as another type of failure of the EVSE system 84.

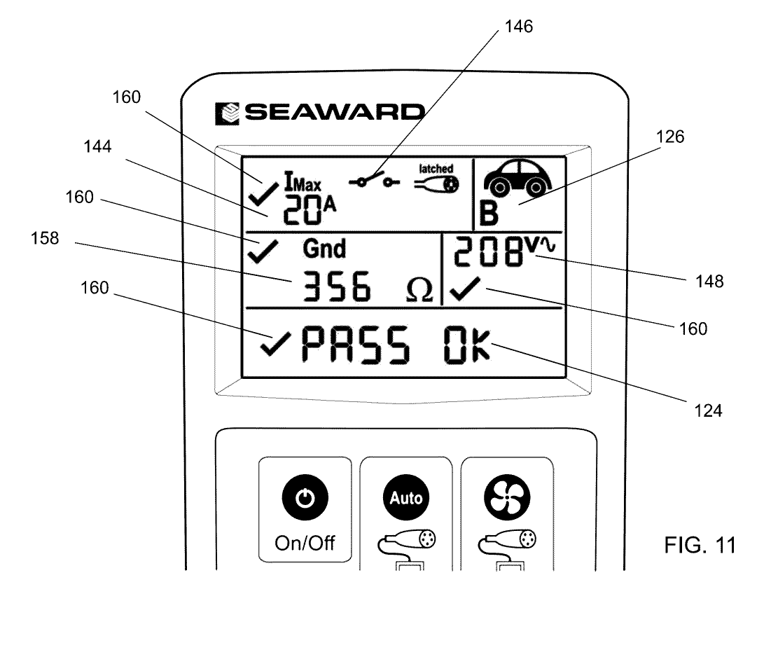

If the supply voltage and ground resistance is within a specified tolerance as set through the defaults of the EV100 tester 30 or through the EV100 tester software application 10, the operational status indicator 124 will display “PASS OK” to indicate the EVSE 84 is functioning properly to initiate the charging of an EV, as shown in FIG. 11. A pass symbol 160 is displayed with each reading within the display 40 for an operator to quickly note that the measured and calculated readings are within specified tolerances. The pass symbol 160 indicates that the calculated maximum current 144, the supply voltage reading 148, and the calculated ground connection resistance 158 are all within the specified tolerance as provided within the display 40. These readings are transmitted to the EV100 tester software application 10 for recording and display.

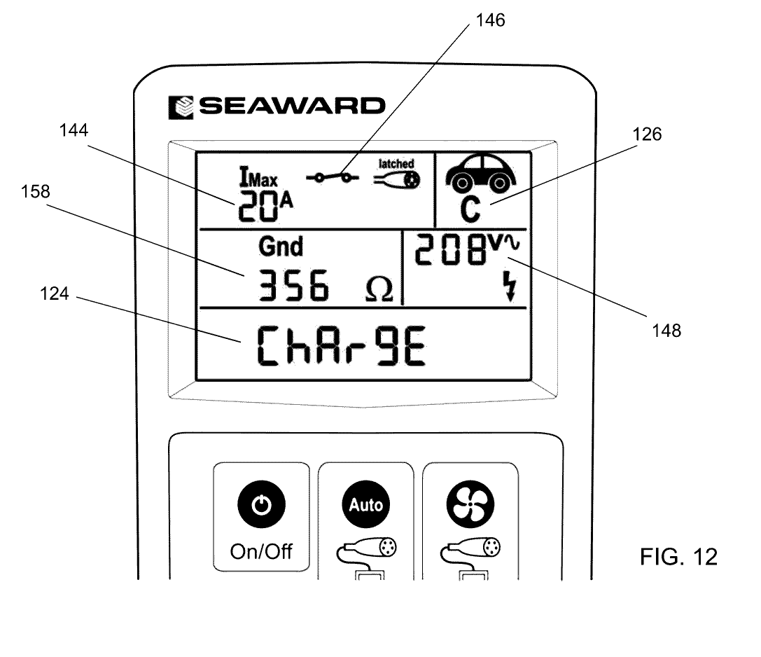

The EV100 tester 30 will adjust the duty cycle of the PWM signal at the CP line 134 that is at +/−6VDC to signal to the EVSE 84 to close the main power contact and begin to supply power causing a transition of the EV detection status 126 or transition state from “State B” to “State C” with the EV100 tester 30 measuring and recording the time taken for this transition by the EVSE 84. This transition time is transmitted to the EV100 tester software application 10 and the EV detection status 126 will show the new status as “C” as shown in FIG. 12. The main power contact indicator 146 in the display 40 will show the contact as closed and the operational status indicator 124 will display “CHARGE” within the display 40 while the EVSE 84 is supplying power to the simulated EV. The PWM pilot signal at the CP line 134 is measured and all data signals are recorded by the EV100 tester 30 during charging including the PWM positive peak voltage 136, the negative peak voltage 138, the PWM frequency 140, and the PWM duty cycle 142. Any of these measurements may be selected using the operational controls at a point in time during testing of the EVSE 84 and be displayed in the measured values 54 of the EV100 tester display 40. The EV100 tester 30 uniquely provides information on the test being performed, the status of the EVSE 84, such as showing the main power contact as closed, the detection status also referred to as the transition state of the EVSE 84, the actual reading of a measured or calculated value and further provides fault symbols 156 to indicate that a measured or calculated value is outside specified tolerances and pass symbols 160 to indicate that the measured or calculated value is within specified tolerances.

All measurements are recorded by the EV100 tester 30 and are available to be transmitted to the EV100 tester software application 10 which includes features to record and display any of the measured and calculated test data and may display the full PWM pilot signal graphically for analysis to diagnose faults within the EVSE system 84. The EV100 tester software application 10 also provides visual indicators to show measurements within or outside of specified tolerances including the identification of failures within the PWM signal removing the necessity for an operator to use an oscilloscope to determine faults within the PWM pilot signal that may result in failures in communication between the EVSE 84 and EV and in failures in the operation of the EVSE 84. By transmitting all of measured and calculated data to the EV100 tester software application 10, the test data may be remotely reviewed in real-time for a remote technician to assist an operator with diagnosis and repair of a failure or be stored for review and tracking of the performance characteristics of the EVSE 84 over time, such as to validate the performance after the replacement of a part for repair.

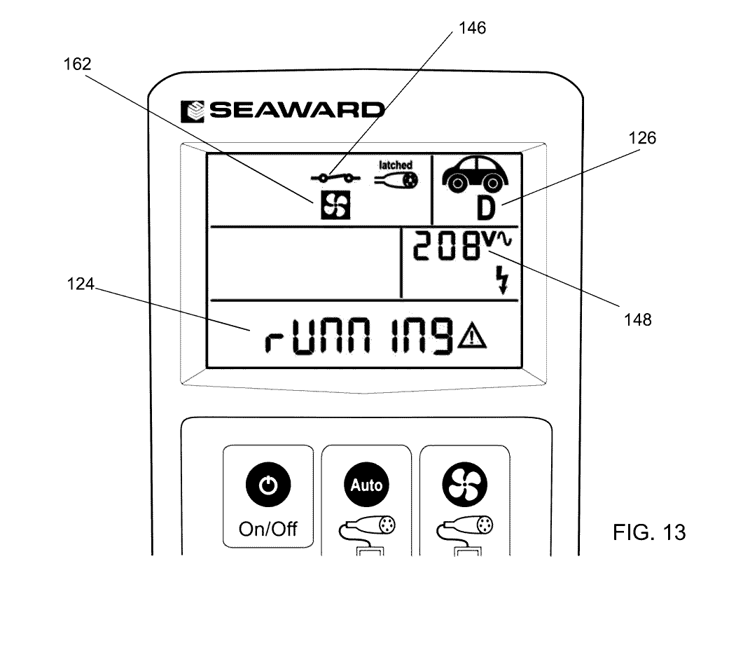

For some electric vehicles, a ventilation system such as a fan must be used to properly maintain a cool temperature while charging. The EVSE 84 must turn the ventilation system on prior to charging or if the EVSE 84 does not have a ventilation system then not supply power to the vehicle and instead provide an indicator that the EVSE 84 will not charge the EV because it does not have a ventilation system. If the venting system fan check operational control 74 is selected, the EV100 tester 30 signals the EVSE 84 through a change in the duty cycle of PWM pilot signal on the CP line 134 to simulate an EV requiring a venting system. The display provides a vent system indicator 162 when the vent fan check operational control 74 is selected and the operational status indicator 124 will display “RUNNING” if the EVSE 84 properly turns on the ventilation system of the EVSE 84 prior to charging, as shown in FIG. 13. The EVSE 84 will then close the main power contact as shown by the indicator 146 within the display 40 to begin charging. The EV detection status 126 will transition from “State B” to “State D” to indicate that the charging test being performed is also testing the ventilation system. The ventilation system may remain running during the charging test and may be monitored by the EV100 tester 30 with a fault indicator displayed if the ventilation system fails during testing. The operational status indicator 124 will also indicate a fault if the ventilation system of the EVSE 84 does not turn on prior to charging, or if the EVSE is not equipped with a ventilation system, and does not indicate that the EVSE cannot charge, and/or if the EVSE begins charging after receiving a signal that a ventilation system is required by the simulated EV.

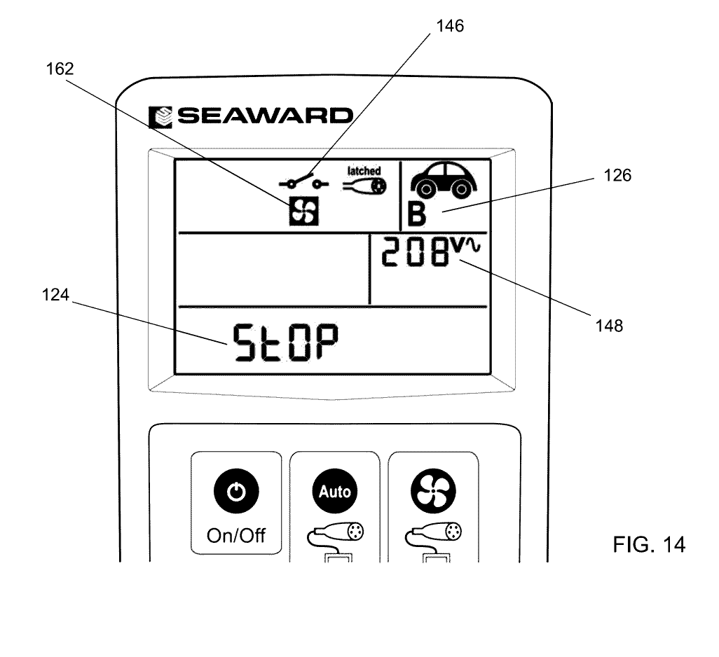

As shown in the operational timing diagram of FIG. 8, initially when selecting the power on operational control 70, the EV100 tester 30 is ready and EV detection status 126 or transition state is at “State A.” At t1, the operator connects the EV100 tester 30 to the EVSE 84 directly or using a test cable and/or the adaptor cable 90 and EV detection status 126 transitions to “State B.” A maximum availability current test of the EVSE 84 is performed to confirm the adjustment of the maximum available charging current based on the simulated EV and supply adaptor cable 90. If the EVSE 84 adjusts the maximum available charging current properly or indicates that the current supplied will be below the EV or supply cable current rating, the supply line voltage will be measured and the ground resistance will be calculated and if passing, a ventilation system test may also be performed and if passing, at t2 the EV100 tester 30 will send a signal to drop the CP line voltage to 6V to signal to the EVSE to begin charging. The main power contact of the EVSE 84 is closed at t3 and the EV detection status 126 transitions from “State B” to “State C” or to “State D” if a ventilation system test is running to begin charging of the simulated EV. During charging, the EV100 tester 30 measures the charging PWM positive peak voltage 170, the charging negative peak voltage 172, the charging PWM frequency 174, and the charging PWM duty cycle 176. The charging PWM measurements are recorded and transmitted to the EV100 tester software application 10. At t4 a signal from the EV100 tester 30 is sent to increase the CP line voltage to end charging and the EV detection status 126 transitions from “State C” or “State D” if a ventilation system is also under test to “State E” to signal the EVSE 84 to open the main power contact. The EV100 tester 30 measures and records the time taken for the transition from one detection status or transition state to the next and this data is transmitted to the EV100 tester software application 10. At t5 the EVSE is disconnected from the EV100 tester 30 and at t6 the EV detection status 126 transitions to “State F” and a test completed signal is transmitted to the EV100 tester software application 10 and the EVSE supply cable 86 is removed. The stopping of testing at any time during testing or at the completion of testing may be done by the operator by selecting the stop operational control 80. At the end of testing or when the stop operational control is pressed at any time during testing the operational status indicator 124 displays “STOP” and the main power contact indicator 146 shows the switch as open, as shown in FIG. 14. Alternatively, testing of the EVSE 84 may be performed automatically or remotely using commands programmed or initiated by the EV100 tester software application 10 using a mobile or other digital device to perform maintenance, monitor the performance characteristics to verify a repair or to complete other operational performance mandates as required.

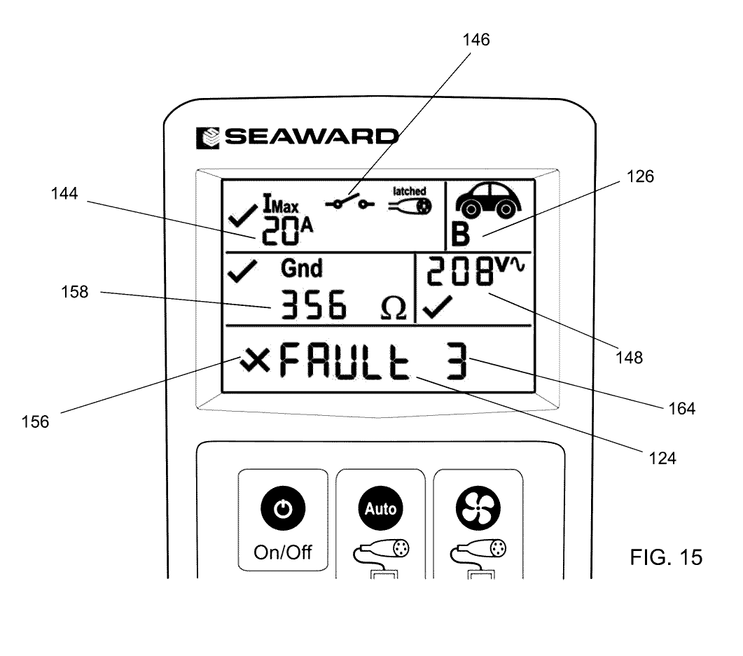

The EV100 tester 30 can simulate a number of fault conditions that may occur including faults within the EV onboard charge control circuitry. These fault conditions may be applied during charging when the EV detection status 126 or transition state is in the “State C” or “State D” in order to stress the EVSE system 84 under real operational conditions. The fault conditions may include an open circuit diode fault, a short circuit diode fault, and the control pilot line voltage CP shorted to ground. More complex fault conditions such as PWM voltage, timing, duty cycle or transition states may be displayed within the EV100 tester display 40 with the operational status indicator 124 displaying the status as “FAULT” with a fault code 164 that identifies the identified failure, as shown in FIG. 15. Conditions related to the fault code 164 and other information may be described within a product handbook, or within the EV100 tester software application graphical user interface, for an operator or other user to easily access on their mobile or other digital device and find information about a failure. The selection to run a particular fault condition is optionally selected by the operator. This allows the operator 29 to select which fault conditions are applied and prevent choosing a fault condition that in some EVSE systems 84 may cause extended down time to the system. While some EVSE systems 84 will automatically recover from a selected fault condition as soon as the fault condition is removed, other EVSE systems 84 may require some form of reset to be operational after the fault condition. Through the fault condition testing the EV100 tester 30 measures and records performance characteristics such as the time for response by the EVSE, the notification of a fault by the EVSE, shut down, and/or the recovery of the EVSE as well as the correct operational performance of the EVSE 84 in response to the fault condition. The EV100 tester 30 may further provide verification of the charging voltage, the maximum available charging current, the resistance of the ground connection, the time of transition and detection of a change in the EV detection status or transition states (A, B, C, D, E, F) and other information on the status of the EVSE while a fault condition test is being performed.

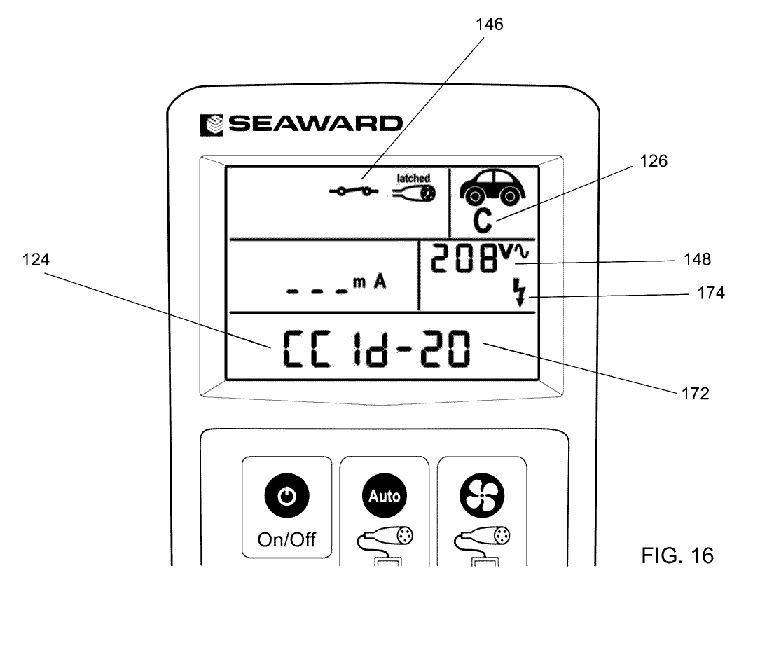

By selecting the ground fault current interrupter (GFCI) operational control 76, the EV100 tester 30 performs the initialization steps of measuring the charging voltage, determining the maximum available charging current, and calculating the resistance of the ground connection. The EV100 tester 30 will then simulate a request for charging, transitioning the EV detection status or transition state to “State C” and causing the EVSE 84 to close the main power contact 146 as shown in the display 40 in FIG. 16. The EV100 tester 30 measures the main power voltage to confirm the EVSE 84 is operating within a specified tolerance as set through the defaults of the EV100 tester 30 or through the EV100 tester software application 10. The EV100 tester 30 will then produce a controlled fault current in the ground conductor and measure and record the main AC power voltage at the EVSE 84 output using the GFCI test signal generation circuit 168 and GFCI current generator 170 of the measurement board 108. The fault current produced by the EV100 tester 30 is in accordance with the requirements of IEC 61557-6 as is the measurement performance of the EV100 tester 30.

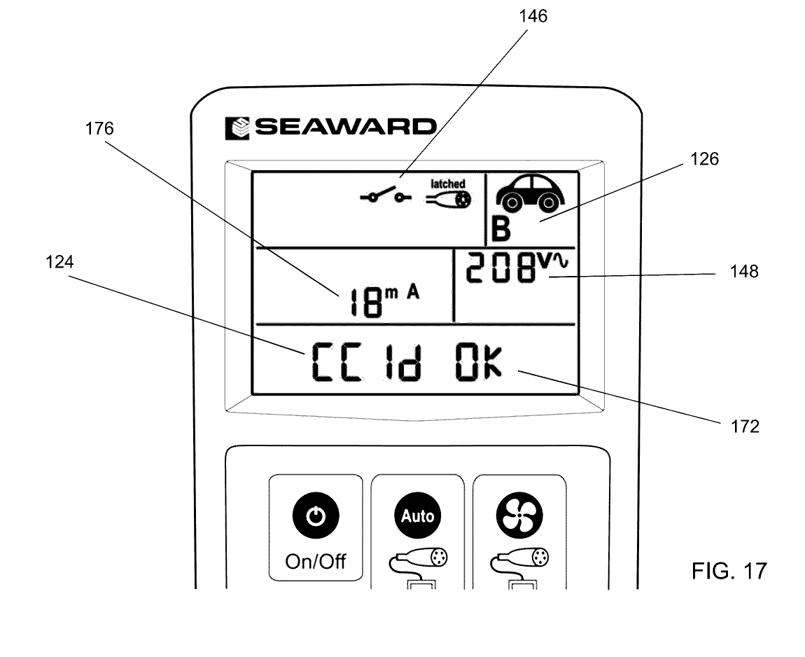

The magnitude of the fault current 172 is displayed as the fault current is increased in steps from 5 mA to 25 mA with a fault current indicator 174 shown in the display while testing. As the current increases a charging circuit interrupting device (CCID) within the EVSE 84 will interrupt the flow of AC power to the EVSE 84 if the difference in current flowing between the power terminals of L1 and N, L2 and L3, or between L3 and N in the case of a three phase voltage supply exceeds a predetermined threshold of the EVSE 84 indicating a potential ground fault condition. If the CCID as indicated within the operational status indicator 124 opens the main power contact 146 and shuts down the AC power to the EVSE 84 at the predetermined threshold, the measured tripping current 176 is shown within the display 40 and the fault code 164 shows an “OK” indicating passing of the GFCI test, as shown in FIG. 17. If the CCID does not stop the flow of AC power before the fault current of the GFCI test reaches its maximum amplitude, the test is terminated and a fault code 164 and the measured voltage is shown within the display 40. The EV100 tester 30 includes a zero crossing detect circuit 178 to perform fast and accurate frequency measurements and reduce frequency and phase measurement errors when comparing current measurements during the GFCI and other testing.

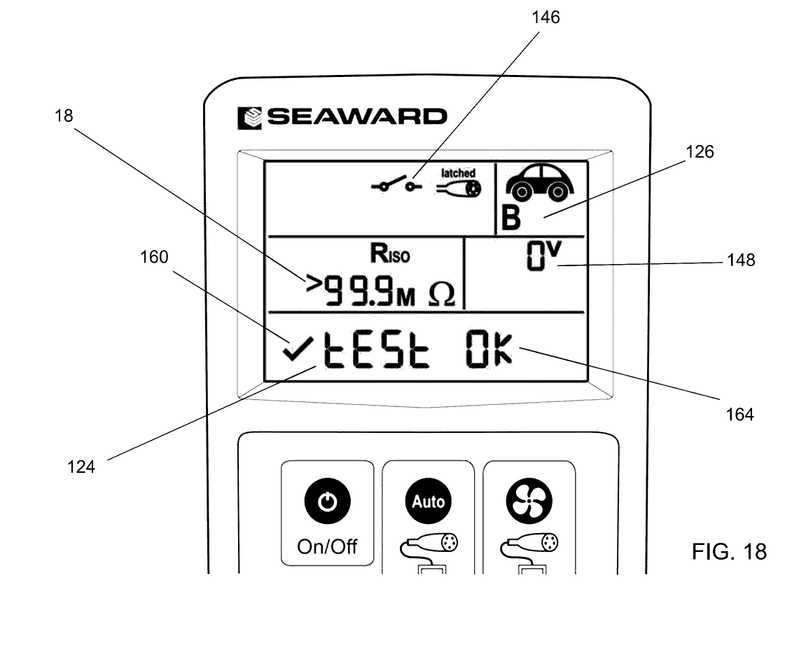

Further tests available to be performed by the compact and easy to use EV100 tester 30 include insulation resistance testing. In charging an EV, a vehicle owner must connect and disconnect the cable between the EV and EVSE 84. It is important that there is adequate electrical isolation between live conductors and ground to ensure there is no risk of electric shock to the vehicle owner, an operator or other user of the EVSE 84. In performing the insulation resistance test, the EVSE supply cable 86 is connected to the EV100 tester 30 using the adaptor cable 90. The operator selects the cable insulation test operational control 78 which causes the EV100 tester 30 to apply a test voltage of 500VDC between the live conductor power terminals (L1, L2 L3, N) and ground using the insulation test voltage circuitry 180 of the measurement board 108. The operational status indicator 124 displays “TEST” to indicate the 500VDC is being applied. The EV100 tester 30 measures and records any resulting current flow and calculates the insulation resistance 182 which is shown within the display 40 and recorded. If the calculated resistance is within a specified tolerance as set through the defaults of the EV100 tester 30 or through the EV100 tester software application 10, the fault code 164 shows an “OK” indicating passing of the cable insulation test, as shown in FIG. 18.

All measurements, calculations, results, status and other operational performance information and characteristic data of the EVSE 84 is transformed using an analog to digital converter (ADC) 190 and the microcontroller 106 of the measurement board 108. This information is then processed using the main microcontroller 110 of the processor board 112 to record and store all data within onboard memory and data storage components 192 and transform data for display using display components 194 to provide a recognizable output for an operator or other user on the display 40 of the EV100 tester 30. The main microcontroller 110 receives, transforms and distributes commands received from an operator 29 using user input circuitry 196 on the processor board 112 of the EV100 tester 30 to the microcontroller 106 of the measurement board 108. Operator or user inputs may also be received from a wireless communication interface 198 and/or a near field communication transmission circuitry 200 with received data transmitted to the main controller 110 to receive, transform and distribute the input commands to the measurement board 108.

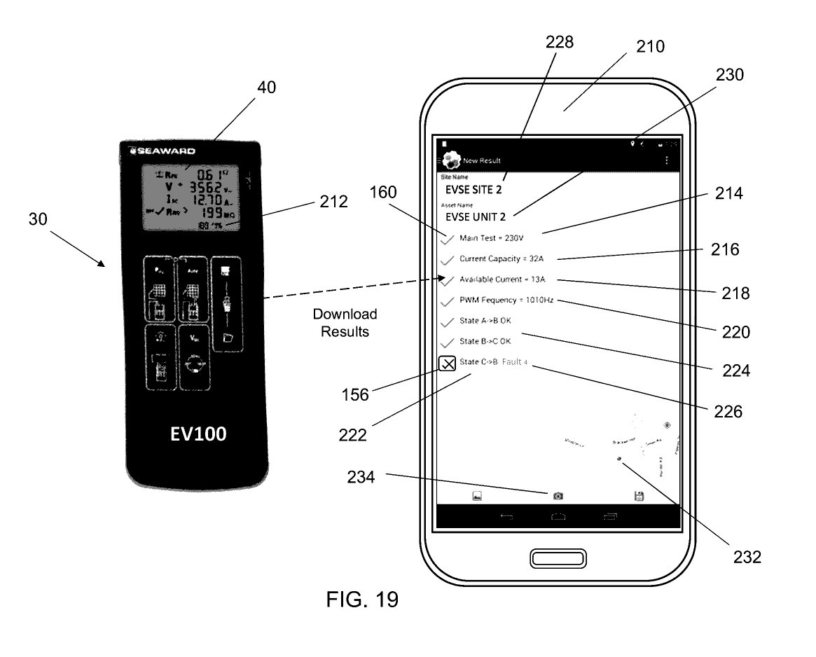

The near field communication transmission circuitry 200 also provides for the transfer of all data from the EV100 tester 30 to a mobile device 210 of the operator or other user. At the end of a test sequence a data status transfer indicator 212 within the display 40 shows that data is available for transfer. The mobile device 210 having near field communication is placed near or in contact with the EV100 tester 30 to automatically initiate the transfer of test results and performance characteristics of the EVSE 84 to the mobile device 210 within the EV100 tester software application 10, as shown in FIG. 19. In embodiments of the EV100 tester software application 10 installed as a mobile app or accessible through a web browser, the EVSE test results may be recorded and displayed. These test results may include the main supply AC voltage 214, the maximum current capacity 216, the available current 218, the PWM frequency 220, and the EV detection status or transition states 222. Acceptable performance of the EVSE 84 may be shown with pass symbols 160 and fault symbols 156 with pass status codes 224 and fault codes 226 or other performance indicators.

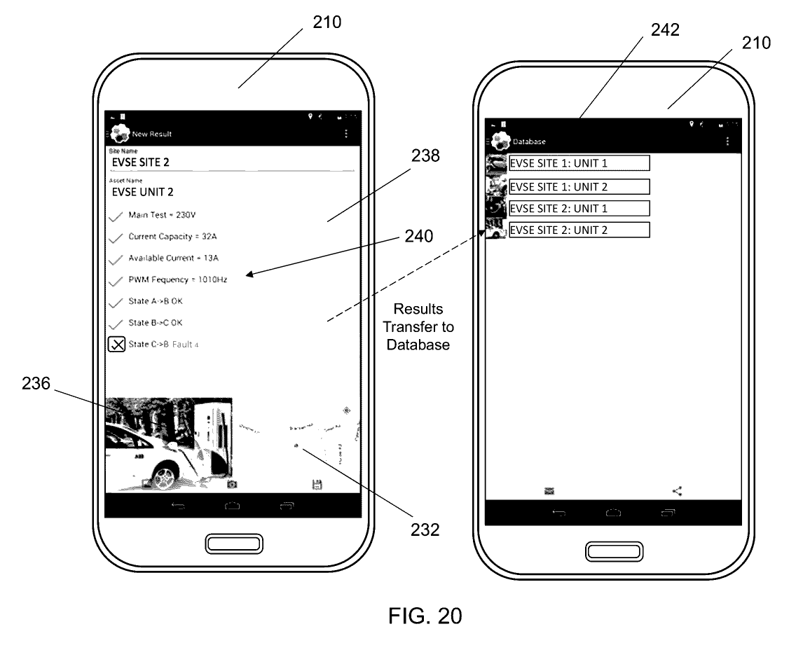

The EV100 tester software application 10 may provide a dialog box for an operator to enter the site name 228 and unit name 230 for the EVSE 84 under test or for other notes on issues encountered during testing. The EVSE location 232 may also be displayed through the integration of GPS mapping data from the mobile device implemented using the EV100 tester software application 10. The EV100 tester software application 10 may further provide for the operator to take a picture of the EVSE 84 using a camera feature 234 of the mobile device 210 with the EV100 tester software application 10 integrating the picture 236 of the EVSE 84 into the test result display 238, as shown in FIG. 20. The test results 240 may be stored and accessible from the EV100 tester software application database 242 for viewing on any mobile or other digital device by loading the EV100 tester software application 10 on the mobile device or accessing the EV100 tester software application 10 through a web browser.

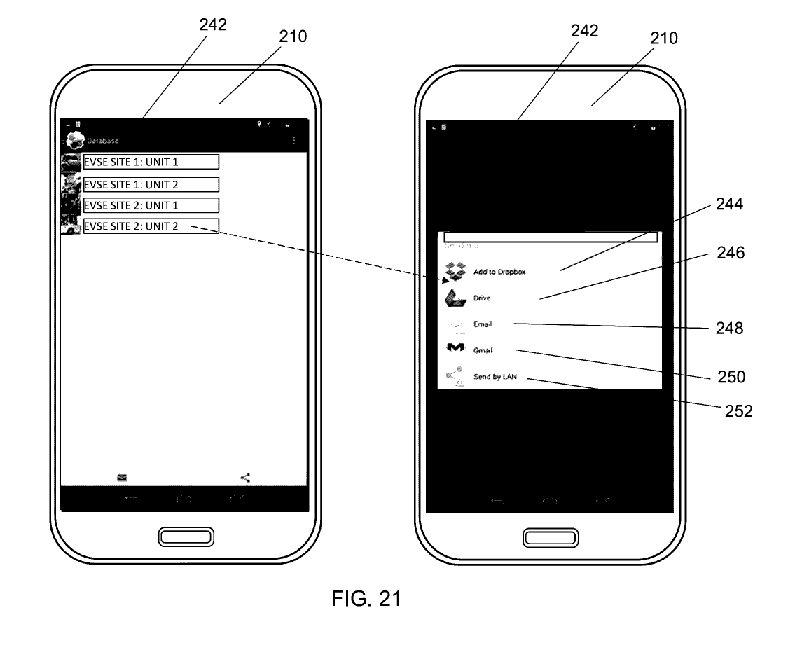

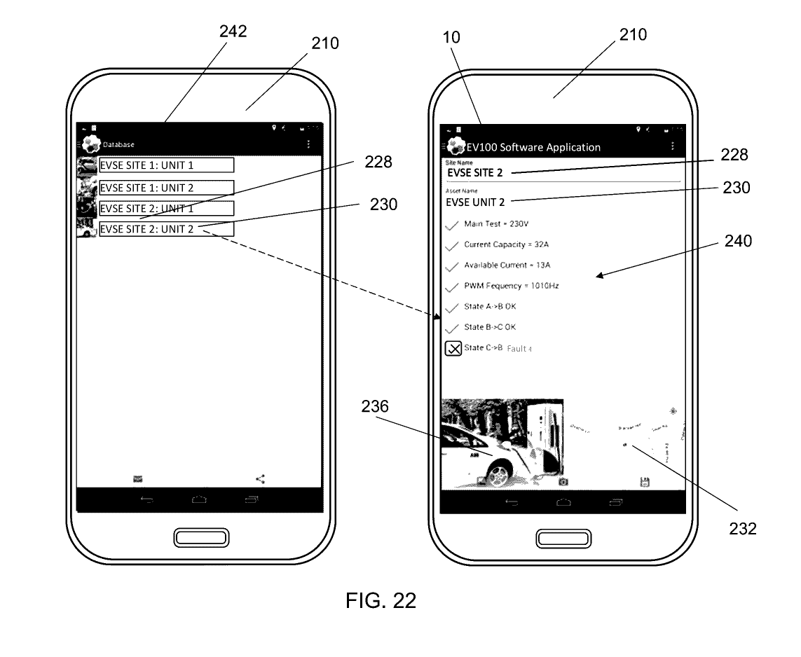

The EV100 tester software application 10 further provides for test results 240 from the database 242 to be transmitted to a cloud server such as a drop box 244 or Google drive 246. The test results 240 may further be emailed using the mobile device email account 248 or Gmail account 250 or have the test results be directly downloaded 246 from the mobile device 210 through a local area network (LAN) 252, as shown in FIG. 21. Once the EV100 tester software application 10 is accessed a user may review test results 240 from the database 242 by selecting the site name 228 and unit number 230 to view the test results 240, as shown in FIG. 22. Access to test results 240 may be restricted through user logins and passwords to prevent unauthorized access. In embodiments of the EV100 tester 30 data transmission of all measurements, calculations, results, status and other operational performance information and characteristic data of the EVSE 84 may transmitted wirelessly, using Wi-Fi, Bluetooth, cellular or other radio-frequency links using the wireless communication interface 198 where the EV100 tester may have only NFC capability, have only wireless capability, or have both depending on the requirements of data transmission and accessibility where wireless integration may be preferable for monitoring and transmission to more remote locations.

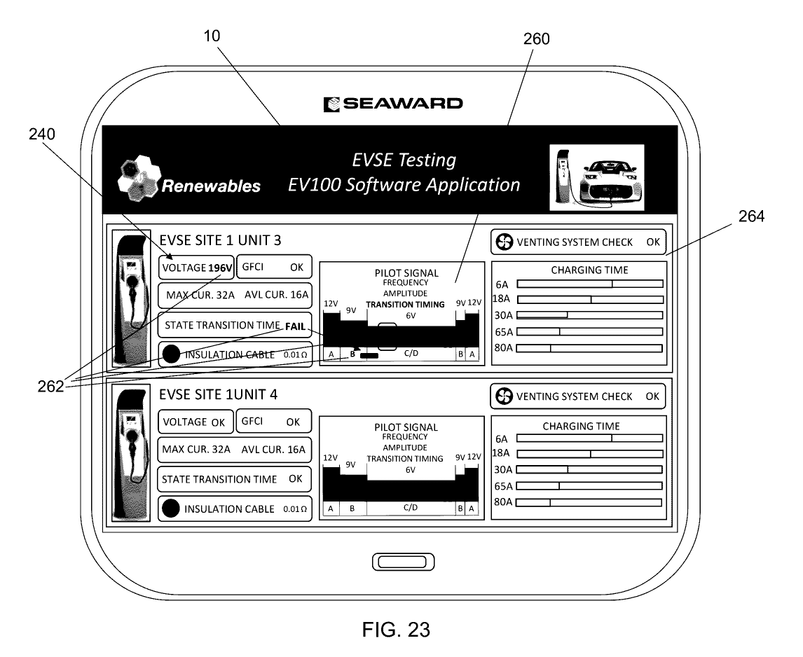

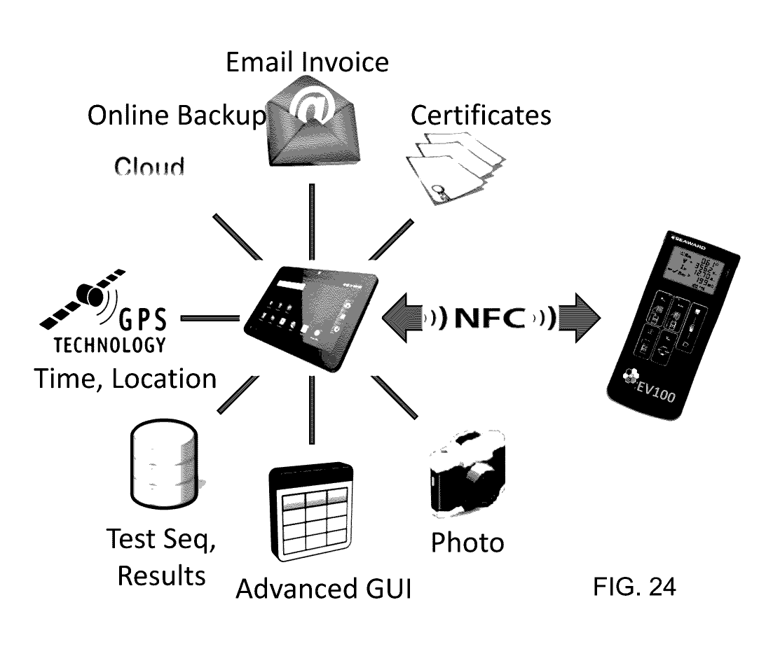

The EV100 tester software application 10 may provide the PWM pilot signal transmission data 260 removing the requirement that an operator 29 use an oscilloscope to diagnose failures related to the pilot signal CP which may cause communication failures or transition delays between the EVSE 84 and EV. The EV100 tester 30 and EV100 tester software application 10 further include default tolerance settings based on specification parameters and regulatory requirements of various EVSE systems which provides for failures and status to be displayed using fault symbols 156, status indicators 160 and diagnostic indicators 262 for any measured or calculated value. The EV100 tester software application 10, as shown in FIG. 23, may use diagnostic indicators 262 such as flashing text, changing colors, arrows, boxes or other indicators to highlight anomalies where the measured and expected readings are outside of tolerance specifications. By providing a dedicated comprehensive testing tool, the EV100 tester 30 and EV100 tester software application 10 may be used by lower level operators in the field to identify and repair some more basic failures and be used by highly skilled technicians to remotely review test results and diagnose readings to determine the cause and proper repair of more extensive failures of the EVSE 84. The EV100 tester software application 10 may further provide additional information such as measurements of current analysis and charging time 262 to manage power usage from a utility company, and other performance data and characteristics of the EVSE 84 under test. Further embodiments may provide real-time monitoring by having EV100 tester 30 integrated or automatically periodically connected to the EVSE 84 during off hours to interrogate performance of the EVSE 84. The EV100 tester 30 and EV100 tester software application 10 may further provide for remote testing for maintenance or repair verification through automated transmission of data to a local area network within the EVSE site or to a remote maintenance facility, that may deploy operators as needed for EVSE systems 84 showing failures, faults or other characteristics outside of performance specifications. As shown in FIG. 24, the EV100 tester software application 10 provides for universal access to test results using NFC and/or wireless communication that with the comprehensive testing protocols and diagnostics of the EV100 tester 30 provides for maintenance, repair, and certification of EVSE systems 84 and assures safe and reliable performance in charging electric vehicles.

The invention has been described in detail with particular reference to certain preferred embodiments thereof, but it will be understood that variations and modifications can be effected within the spirit and scope of the invention.

What is claimed is:

1. An electric vehicle supply equipment tester, comprising:
a housing;
a display panel;
operational controls;
circuitry comprising a microprocessor and memory disposed in the housing to measure, calculate, record and transmit performance characteristic data of an electric vehicle supply equipment charging station; and
wherein information on the test being performed, the status of the electric vehicle supply equipment charging station, the transition states of the electric vehicle supply equipment charging station, and the actual reading of a measured or calculated value is displayed within the display panel.

2. The electric vehicle supply equipment tester of claim 1 comprising a wireless interface to transmit performance characteristic data from the electric vehicle supply equipment tester for recording and display within an electric vehicle supply equipment tester software application implemented on a digital device, the digital device having a microprocessor, memory, data storage, and an output device for the transformation and display of data recognizable to a user.

3. The electric vehicle supply equipment tester of claim 2 wherein the electric vehicle supply equipment tester and electric vehicle supply equipment tester software application comprising status indicators displaying information recognizable to a user indicating performance characteristic data as within or exceeding acceptable tolerance specifications and record and display pass symbols within the display of an output device to indicate that a measured or calculated value is within specified tolerances and to record and display fault symbols within the display of an output device to indicate that a measured or calculated value is outside specified tolerances.

4. The electric vehicle supply equipment tester of claim 1 wherein pass symbols are displayed within the display panel to indicate that a measured or calculated value is within specified tolerances and fault symbols are displayed within the display panel to indicate that a measured or calculated value is outside specified tolerances.

5. The electric vehicle supply equipment tester of claim 2 wherein the electric vehicle supply equipment tester software application records and displays measured and/or calculated values and pulse width modulation signals of the performance characteristic data and transition states and timing of changes in transition states of the electric vehicle supply equipment charging station within the display of the output device removing the requirement of an oscilloscope for diagnosis.

6. The electric vehicle supply equipment tester of claim 1 comprising proximity drive circuitry to simulate the connection of an electric vehicle to the electric vehicle supply equipment charging station.

7. The electric vehicle supply equipment tester of claim 1 comprising a plurality of adaptor test cables to simulate various current ratings of different electric vehicles.

8. The electric vehicle supply equipment tester of claim 1 comprising proximity simulation control circuitry to simulate various current ratings of different electric vehicles.

9. The electric vehicle supply equipment tester of claim 1 comprising pulse width modulation positive peak measurement circuitry, pulse width modulation negative peak measurement circuitry, and pulse width modulation frequency/duty cycle measurement circuitry for the measurement of a pulse width modulation signal.

10. The electric vehicle supply equipment tester of claim 1 comprising phase-ground loop resistance measurement circuitry for the calculation of ground resistance.

11. The electric vehicle supply equipment tester of claim 1 comprising ground fault current interrupter test signal generation circuitry and a ground fault current interrupter current generator to test the ground fault current, ground fault current interrupter and charging circuit interrupting device of an electric vehicle supply equipment charging station.

12. The electric vehicle supply equipment tester of claim 1 comprising insulation test voltage circuitry to test the insulation of an electric vehicle supply equipment charging station supply cable.

13. A method of testing an electric vehicle supply equipment charging station comprising:
measuring performance characteristics of an electric vehicle supply equipment charging station;
calculating performance characteristics of the electric vehicle supply equipment charging station; and
recording and displaying measured and calculated performance characteristic data.

14. The method of testing an electric vehicle supply equipment charging station of claim 13 comprising transmitting all measured and calculated performance characteristic data to an electric vehicle supply equipment tester software application implemented on a digital device, the digital device having a microprocessor, memory, data storage, and an output device for the transformation and display of the measured and calculated performance characteristic data in a form recognizable to a user.

15. The method of testing an electric vehicle supply equipment charging station of claim 13 comprising recording and displaying status indicators as information recognizable to a user indicating performance characteristic data as within or exceeding acceptable tolerance specifications.

16. The method of testing an electric vehicle supply equipment charging station of claim 13 comprising recording and displaying information on the test being performed, the status of the electric vehicle supply equipment charging station, the detection status of the electric vehicle supply equipment charging station, and test results indicating the actual reading of a measured or calculated value.

17. The method of testing an electric vehicle supply equipment charging station of claim 13 comprising:
selecting an auto operational control;
connecting the electric vehicle supply equipment charging station to an electric vehicle supply equipment tester, the electric vehicle supply equipment tester simulating the connection of an electric vehicle;
setting on the tester a maximum current to be tested;
measuring the maximum charging current supplied by the electric vehicle supply equipment charging station;
determining if the maximum charging current is within a specified range of the maximum current set by the tester;
recording and displaying a status indicator indicating the maximum charging current of the electric vehicle supply equipment charging station as passing if within the specified range; and
recording and displaying a status indicator indicating the maximum charging current of the electric vehicle supply equipment charging station as failing if outside the specified range.

18. The method of testing an electric vehicle supply equipment charging station of claim 13 comprising:
selecting a maximum current to be tested based on the maximum current rating of a cable adaptor;
connecting the electric vehicle supply equipment charging station to the cable adaptor;
connecting the cable adaptor to an electric vehicle supply equipment tester;
measuring the maximum charging current supplied by the electric vehicle supply equipment charging station;
determining if the maximum charging current is within a specified range of the maximum current set by the cable adaptor;
recording and displaying a status indicator indicating the maximum charging current of the electric vehicle supply equipment charging station as passing if within the specified range; and
recording and displaying a status indicator indicating the maximum charging current of the electric vehicle supply equipment charging station as failing if outside the specified range.

19. The method of testing an electric vehicle supply equipment charging station of claim 13 comprising:
connecting the electric vehicle supply equipment charging station to a cable adaptor;
connecting the cable adaptor to an electric vehicle supply equipment tester;
applying a test voltage between the power terminals and ground of the electric vehicle supply equipment charging station;
measuring any current flow;
calculating and displaying the insulation resistance;
determining if any current flow is within a specified tolerance;
recording and displaying a status indicator indicating the current flow and insulation resistance as passing if within the specified tolerance; and
recording and displaying a status indicator indicating the current flow and insulation resistance as failing if outside the specified tolerance.

20. The method of testing an electric vehicle supply equipment charging station of claim 13 comprising:
detecting, recording and displaying the connection of the electric vehicle supply equipment charging station to an electric vehicle supply equipment tester;
recording and displaying a detection status as “State A”;
detecting a reduction in the control pilot signal from +/−12 VDC to +/−9 VDC simulating the connection of an electric vehicle using the electric vehicle supply equipment tester;
recording and displaying the detection status as “State B”;
measuring and recording the pulse width modulation positive peak voltage;
measuring and recording the pulse width modulation negative peak voltage;
measuring and recording the pulse width modulation frequency;
measuring and recording the pulse width modulation duty cycle;
detecting a reduction in the control pilot signal from +/−9 VDC to +/−6 VDC;
detecting, recording and displaying the closing of the main power contact;
supplying power to the electric vehicle supply equipment tester simulating the connection of an electric vehicle;
recording and displaying the detection status as “State C”;
detecting, recording and displaying the opening of the main power contact;
stopping the supply of power to the electric vehicle supply equipment tester simulating the connection of an electric vehicle;
recording and displaying the detection status as “State E”
detecting the disconnection of the electric vehicle supply equipment charging station to the electric vehicle supply equipment tester;
recording and displaying a detection status as “State F”.

21. The method of testing an electric vehicle supply equipment charging station of claim 13 comprising:
selecting the vent fan check operational control;
simulating an electric vehicle requiring a ventilation system;
determining that the electric vehicle supply equipment charging station has a ventilation system and that the ventilation system turns on prior to charging;
displaying at least one indicator showing the ventilation system as running and the electric vehicle supply equipment charging station as charging;
recording and displaying the detection status as “State D”.

22. The method of testing an electric vehicle supply equipment charging station of claim 21 comprising:
determining the electric vehicle supply equipment charging station does not have a ventilation system;
determining the electric vehicle supply equipment charging station provides an indicator that the electric vehicle charging station will not charge because it does not have a ventilation system;
determining that the electric vehicle charging station does not provide a charge;
recording and displaying a status indicator as passing if the electric vehicle charging station does not provide a charge.

23. The method of testing an electric vehicle supply equipment charging station of claim 13 comprising:
selecting the ground fault current interrupter operational control;
calculating the resistance of the ground conductor connection of the electric vehicle supply equipment charging station;
producing a controlled fault current in the ground conductor connection;
increasing the controlled fault current to a maximum controlled fault current;
determining if the ground fault current interrupter stops the flow of AC power to the electric vehicle supply equipment charging station prior to reaching a predetermined threshold for the controlled fault current;
recording and displaying at least one status indicator as passing if the ground fault current interrupter stops the flow of AC power to the electric vehicle supply equipment charging station prior to reaching the predetermined threshold for the controlled fault current; and
recording and displaying at least one status indicator as failing if the ground fault current interrupter does not stop AC power to the electric vehicle supply equipment charging station prior to the controlled fault current reaching the predetermined threshold for the controlled fault current.

24. A computer readable medium of instructions for testing an electric vehicle supply equipment charging station, comprising:
instructions for measuring performance characteristics of an electric vehicle supply equipment charging station;
instructions for calculating performance characteristics of the electric vehicle supply equipment charging station; and
instructions for recording and displaying measured and calculated performance characteristic data.

25. The computer readable medium of instructions for testing an electric vehicle supply equipment charging station of claim 24, comprising:
instructions for transmitting, recording and displaying all measured and calculated performance characteristic data within a software application implemented on a digital device, the digital device having a microprocessor, memory, data storage, and an output device for the transformation and display of data recognizable to a user.

26. The computer readable medium of instructions for testing an electric vehicle supply equipment charging station of claim 25, comprising:
instructions for recording and displaying status indicators as information recognizable to a user indicating performance characteristic data as within or exceeding acceptable tolerance specifications.

27. The computer readable medium of instructions for testing an electric vehicle supply equipment charging station of claim 25, comprising:
instructions for recording and displaying information on the test being performed, the status of the electric vehicle supply equipment charging station, the detection status of the electric vehicle supply equipment charging station, the time for transition between states of the detection status, and test results indicating the actual reading of measured and calculated values.

28. The computer readable medium of instructions for testing an electric vehicle supply equipment charging station of claim 25, comprising:
instructions for determining the selection of the auto operational control;
instructions determining the connection of the electric vehicle supply equipment charging station to an electric vehicle supply equipment tester, the electric vehicle supply equipment tester simulating the connection of an electric vehicle;
instructions for setting a maximum current to be tested;
instructions for measuring the charging voltage of the electric vehicle supply equipment charging station;
instructions for measuring the maximum charging current supplied by the electric vehicle supply equipment charging station;
instructions for determining if the maximum charging current is within a specified range of the set maximum current;
instructions for recording and displaying a status indicator indicating the maximum charging current of the electric vehicle supply equipment charging station as passing if within the specified range; and
instructions for recording and displaying a status indicator indicating the maximum charging current of the electric vehicle supply equipment charging station as failing if outside the specified range.

29. The computer readable medium of instructions for testing an electric vehicle supply equipment charging station of claim 25, comprising:
instructions for determining a maximum current rating of a cable adaptor;
instructions for determining the connection of the electric vehicle supply equipment charging station to the cable adaptor;
instructions for determining the connection of the cable adaptor to an electric vehicle supply equipment tester;
instructions for measuring the charging voltage of the electric vehicle supply equipment charging station;
instructions for measuring the maximum charging current supplied by the electric vehicle supply equipment charging station;
instructions for determining that the maximum charging current is within a specified range of the maximum current set by the cable adaptor;
instructions for displaying a status indicator indicating the maximum charging current of the electric vehicle charging station as passing if within the specified range; and
instructions for displaying a status indicator indicating the maximum charging current of the electric vehicle charging station as failing if outside the specified range.

30. The computer readable medium of instructions for testing an electric vehicle supply equipment charging station of claim 25, comprising:
instructions for determining the connection of the electric vehicle supply equipment charging station to the cable adaptor;
instructions for determining the connection of the cable adaptor to an electric vehicle supply equipment tester;
instructions for applying a test voltage between the power terminals and ground of the electric vehicle supply equipment charging station;
instructions for measuring any current flow;
instructions for calculating and displaying the insulation resistance;
instructions for determining if any current flow is within a specified tolerance;
instructions for displaying a status indicator indicating the current flow and insulation resistance as passing if within the specified tolerance; and
instructions for displaying a status indicator indicating the current flow and insulation resistance as failing if outside the specified tolerance.

31. The computer readable medium of instructions for testing an electric vehicle supply equipment charging station of claim 25, comprising:
instructions for detecting the connection of the electric vehicle supply equipment charging station to the electric vehicle supply equipment tester;
instructions for displaying a detection status as “State A”;
instructions for detecting a reduction in the control pilot signal from +/−12 VDC to +/−9 VDC to simulate the connection of an electric vehicle using the electric vehicle supply equipment tester;
instructions for displaying the detection status as “State B”;
instructions for measuring, recording and displaying the pulse width modulation signal comprising a positive peak voltage, a negative peak voltage, a modulation frequency, and duty cycle;
instructions for detecting a reduction in the control pilot signal from +/−9 VDC to +/−6 VDC;
instructions for detecting the closing of the main power contact;
instructions for supplying power to the electric vehicle supply equipment tester simulating the connection of an electric vehicle;
instructions for displaying the detection status as “State C”;
instructions for detecting the opening of the main power contact;
instructions for stopping the supply of power to the electric vehicle supply equipment tester simulating the connection of an electric vehicle;
instructions for displaying the detection status as “State E”
instructions for detecting the disconnection of the electric vehicle supply equipment charging station to the electric vehicle supply equipment tester;
instructions for displaying the detection status as “State F”.

32. The computer readable medium of instructions for testing an electric vehicle supply equipment charging station of claim 25, comprising:
instructions for determining the selection of the vent fan check operational control;
instructions for simulating an electric vehicle requiring a ventilation system;
instructions for determining that the electric vehicle supply equipment charging station has a ventilation system and turns the ventilation system on prior to charging;
instructions for displaying at least one indicator showing that the ventilation system as running and the electric vehicle supply equipment charging station as charging instructions for displaying the detection status as “State D”.

33. The computer readable medium of instructions for testing an electric vehicle supply equipment charging station of claim 32, comprising:
instructions for determining that the electric vehicle supply equipment charging station does not have a ventilation system;
instructions for determining that the electric vehicle supply equipment charging station provides an indicator that the electric vehicle supply equipment charging station will not charge because it does not have a ventilation system;
instructions for determining that the electric vehicle supply equipment charging station does not provide a charge;
instructions for displaying a status indicator as passing if the electric vehicle supply equipment charging station does not provide a charge.

34. The computer readable medium of instructions for testing an electric vehicle supply equipment charging station of claim 25, comprising:
instructions for determining the selection of the ground fault current interrupter operational control;
instructions for calculating the resistance of the ground conductor connection of the electric vehicle supply equipment charging station;
instructions for producing a controlled fault current in the ground conductor connection;
instructions for increasing the controlled fault current to a maximum controlled fault current;
instructions for determining if the ground fault current interrupter stops the flow of AC power to the electric vehicle supply equipment charging station prior to reaching a predetermined threshold for the controlled fault current;
instructions for recording and displaying at least one status indicator as passing if the ground fault current interrupter stops the flow of AC power to the electric vehicle supply equipment charging station prior to reaching the predetermined threshold for the controlled fault current; and
instructions for recording and displaying at least one status indicator as failing if the ground fault current interrupter does not stop AC power to the electric vehicle supply equipment charging station prior to the controlled fault current reaching the predetermined threshold for the controlled fault current.
